(19) United States
(12) Patent Application Publication
(10) Pub. No.: US 2012/0090667 A1
(43) Pub. Date: Apr. 19, 2012

(54) POWER FLOAT

(75) Inventors: George Jaroslav Cap, Wittia (AU); Ross Woodfield, Warana (AU)

(73) Assignee: Water Innovations Power and Technology Holdings Pty, LTD, Witta (AU)

(21) Appl. No.: 13/378,894

(22) PCT Filed: Jun. 16, 2010
(86) PCT No.: PCT/AU2010/000741

§ 371 Date: Dec. 16, 2011

(30) Foreign Application Priority Data
Jun. 17, 2009 (AU) 2009902780
Nov. 25, 2009 (AU) 2009905769
Feb. 10, 2010 (AU) 2010900524

(51) Int. Cl. H01L 31/048; B65D 88/36

(52) U.S. Cl. 136/251; 220/218

(57) ABSTRACT

A modular floating impermeable rectangular module, with a connective clustering and solar collector carrying capability. The modular configuration is applied to a water surface, in a synergetic combination for the solar generation of power and the prevention of evaporation and/or airborne water and particulate contamination of the water body. Each module is adapted to support a solar collection panel for converting solar energy into electrical energy in which each flotation module is formed from two half shells which connect together to form a module, the outer surfaces of at least one shell being adapted to support a solar collector and each module is adapted on two opposed edge sections for connection in line to form a chain of modules and each solar collector in said chain being connected in electrical series and each chain of modules being connectable laterally to form arrays of modules and each chain of solar collectors being electrically connected in parallel.

This invention relates to a device adapted to ameliorate evaporation of water storages and provide a platform for the solar generation of power.

### BACKGROUND TO THE INVENTION

For some time there has been interest in the covering of water storages to reduce evaporation and to control air and water borne particulate contamination from those storages.

WO 98/12392 discloses a flat polygonal floating body where the faces of the floating body have partly submerged vertical walls with lateral edges. The Device has an arched cover with a hole in the top cover for air exchange.

Australian patent 199964460 discloses a modular floating cover to prevent loss of water from large water storages comprising modular units joined together by straps or ties, manufactured from impermeable polypropylene multi-filament, material welded together to form a sheet with sleeves. The sleeves are filled with polystyrene or polyurethane floatation devices to provide flotation and stiffness to the covers. WO/02/086258 discloses a laminated cover for the reduction of the rate of evaporation of a body of water, the cover comprising of at least one layer of material that is relatively heat reflecting, and another layer of material that is relatively light absorbing and a method of forming the laminated cover.

Australian patent 198429445 discloses a water evaporation suppression blanket comprising of interconnected buoyant segments cut from tyres cut orthogonal to the axis of the tyre and assembled in parallel or staggered array.

Australian patent 200131305 discloses a floating cover with a floating grid anchored to the perimeter walls of the reservoir, and floating over the liquid level inside the reservoir. A flexible impermeable membrane is affixed to the perimeter walls and is loosely laid over the floating grid.

WO2006/010204 discloses a floating modular cover for a water storage consisting of a plurality of modules in which each module includes a chamber defined by an upper surface and a lower surface there being openings in said lower surface to allow ingress of water into said chamber and openings in the upper surface to allow air to flow into and out of said chamber depending on the water level within said chamber to provide ballast for each module and flotation means associated with each module to ensure that each module floats. The modules prevent water evaporation from the area covered and the shape and size is selected to ensure that the modules are stable in high wind conditions and don't form stacks.

Solar generation from arrays of solar collectors have been proposed.

U.S. Pat. No. 7,492,120 discloses a portable PV (photo voltaic) modular solar generator for providing electricity to a stationary electrically powered device. A plurality of wheels is attached to a rechargeable battery container. The solar PV panels generate power for the driving mechanism of the device so that the PV panels can be continually positioned in optimum sunlight. The device contains a rechargeable battery that can be charged via the PV panels. There is a pivotally connected photo-voltaic panel for generating electricity. The energy from this solar generator can be inverted from Dc to AC mains power [via an inverter] and synchronized via computer to be connected to the utility grid if applicable.

These prior art devices are restricted by:
No facility for technology adaption to large/unlimited scale payload carrying capacity and therefore
No utility level power generation capability;
Containment problems on large gated deployments in the event of a Possible Maximum Storm [PMS] with storage level changes, major current changes and trash flow;
Wind stability issues on large deployments due to insufficient product deployment strength, shear strength, integrity and ineffective active mooring strategies;
Water quality issues via the action(s) of the elements [e.g.: long durations of prevailing winds constraining the product to small areas of the storage];
Inability of the product to be clustered/contained in groups/area or moved without the use of booms;
Inability to be moved in controlled orientation;
No embedded power conducting capability;

It is an object of this invention to provide a floating solar generator that also provides evaporation control and ameliorates the disadvantages of the prior art.

### BRIEF DESCRIPTION OF THE INVENTION

To this end the present invention provides an array of modules each adapted to support a solar collection panel for converting solar energy into electrical energy in which each module is formed from at least one half shell and when two half shells are connected form a flotation module, the outer surfaces of said at least one shell being adapted to support a solar collector and each module is adapted on two opposed edge sections for connection in line to form a chain of modules and each solar collector in said chain being connected in electrical series and/or parallel and each chain of modules being connectable laterally to form arrays of modules and each chain of solar collectors being electrically connected to other chains in series or parallel to provide the required output voltages.

Lockable edge connectors are preferably incorporated in the edges of the modular shells. Preferably each shell incorporates a hole to allow air and/or water to move in and out of the formed module. The chains of modules may be connected together using chain connectors that also incorporate electrical conductors. Preferably at least some of the modules are flotation modules to ensure that the arrays are stable on the water surface. The flotation modules allow water to be held as ballast in the bottom half of the module. Additional flotation devices and ballast devices may also be used with the arrays to optimise the stability of the arrays in all weather conditions.

The invention provides a variety of preferred designs consisting of six major component parts: a modular shell, a chain connector, a floatation pod, a ballast pipe adaptor, a ballast pipe, and a floatation bag, all made of High Density Polyethylene (or similar) resin [HDPE], which includes a master batch mix of ‘state of the art’ light stabilizers and light reflecting fillers [e.g.: Titanium Dioxide and/or carbon black] to maximize the stability and longevity of the material.

The Modular Shell: The resin/master batch mix may be injection moulded into a modular shell of:
a) Square equatorial hollow horizontal section;
b) With:
A slight curved shell top/superstructure, with moulded ribbing to enhance the strength with recesses at either side of the ribs to provide fixing points for the payload support structures, or:
In another embodiment: A dome shaped shell top/superstructure with a reinforced perimeter crown, to provide a circular superstructure base for fixed or motorized payload angular positioning;
In other embodiments a specific three dimensional superstructure can be designed to accept different PV payload types with the above attributes.
c) Two opposing sides of the said equatorial base perimeter, have half sided slotted recessed connectors for connection to the chain connector;
d) The remaining two opposing sides of the said equatorial base, are where the module-to-module connection occurs, this connection is called the module chaining connection.
e) As the modules are assembled in chains to form module chains [the length of a cluster], before they [the module chains], are assembled via the chain connector to form the breadth of the cluster. The chaining connector needs to be water tight, strong and lockable. A first embodiment of the chain connector has a combination of half sided male arrow head [in vertical section], and a female receptacle on one and the other a half sided male arrow head [in vertical section], and locking device.
f) A second embodiment of the chain connector has the arrow heads replaced with a pair of slotted and recessed, cross shaped tubes, which are so designed that when two are mated they form a continuous cross shaped tube into which a male shaped locking device is inserted.
g) In another, preferred embodiment, male and female strips with alternate bugle [curved ‘V’] shaped and rectangular protrusions along one edge, are designed to mate. The male protrusions are slotted at the ends and the female slotted through the body such that when mated a locking strip can be inserted into the aligned male and female slots to form a water-tight lock. The advantage of this embodiment is in assembly and disassembly, as all the locks can be inserted/removed from the top-side of the module.
h) Each shell is designed so that when two shells are properly oriented and mated at the base to form a flotation module. The shells also have the capability to lock together as shells or with flotation modules [mated shells] in series ad infinitum, to form modular chains or strings;
i) Each shell has a vent (hole) centrally placed on top of the shell. The vent can be fitted with a light extinction cap, which allows the free ingress and egress of air and water with the exclusion of light.
j) A single shell may incorporate a removable, pressured air filled balloon/floatation bag fitted to expand underneath the shell and extending below the base of the shell, providing floatation support directly under the solar collector supports. The shell may incorporate a sealable cylindrical hole in the centre top or appropriate position, with a screw/twist lock, in the said top. The said cylindrical hole will accept a screwed/twist lock Access Cap, as a closure mechanism, to clamp the air bag washer which incorporates a hole to allow for the placement of the balloon/floatation bag with a [sealed] inflation access point through said hole.
k) This embodiment has the advantage of variable balloon inflation points [limited by the maximum inflation limit of the balloon], allowing a plethora of floatation adjustments previously not possible to the floatation and draught of the module deployment.

The Chain Connector: The resin/master batch mix in this part, may be extrusion moulded into a long extrusion of:
a) A left and right edge (extruded) section with a female recessed receptacle able to accept two mated shells described in section (f) above with the male arrow head described in section (e) above;
b) The said chain connector section has a centrally placed moulded ‘T’ section on top of the extrusion that provides fixing points for the payload superstructure, or
c) The same section has a centrally placed a cutout ‘T’ section on the bottom of the extrusion that provides fixing points for the floatation pods;
d) The extrusion has also two cylindrical tubes placed in proximity to the left and right edges (see (a) above), which accept tethering inserts;
e) The tethering inserts of the chain connector provide external [perimeter] tethering attachment points for the modular cluster and when combined with similar tethering inserts through the module chain lock connector, imparts the cluster with:
Attachment points for translational movement anywhere on the water body;
The capability to vary the number of inserts according to site specific needs;
The capability to specify the patterned arrangement of the inserts to vary the flexibility of the cluster according to the transmission/reflection/dampening of incident wave and/or wave packets;
Perimeter reinforcement of the deployment in the event of wind and wave action when the deployment is subject to large areas of fetch;
Perimeter reinforcement of a specific containment area(s), where the deployment is used as a booming device [whilst providing PV power];
Perimeter reinforcement, of the free-floating deployment of a rectangular support frame, providing a central axial pivot point for single axis circular sun tracking sub-clusters.
f) In another embodiment, the said chain connector section has the moulded ‘T’ section on top of the extrusion removed and the two cylindrical tubes replaced with rectangular copper conductors with a third additional grounding conductor.
The said grounding conductor will provide electrical grounding for elemental static generation and storm activity;
The said grounding conductor will also act as an attachment reinforcing point for module cluster and perimeter tethering.
Each PV Panel connects into the chain connector via the Earth, Positive and Negative connections electrically in parallel.
The chain connector, when terminating at the termination connector housing is bent [in a slow curve] up to the said housing and fixed into place;
Two clusters are fixed in this manner back to back into the said termination connector housing;
The chain connector voltage, current and operational output is remotely monitored and controlled via a PLC programmed unit/computer;
Each chain connector if operational will be connected in series via the said unit/computer, until the required output voltage is achieved;
The Cluster may have some redundant Chain connected modules, which are on standby if light conditions deteriorate and may be connected to maintain the output voltage requirement of the inverter via the said unit/computer;
g) In a further embodiment, the said chain connector section also has the moulded ‘T’ section on top of the extrusion removed and the two cylindrical tubes removed. The extrusions are replaced with a single or double set of three circular receptacles, able to accept circular conductors as an alternative to the three rectangular copper conductors. The Circular conductors can be pressed into the receptacles, which can be covered with a clip on cover if required. The cables can be routed directly into the base of the terminal connector for connection to the cluster series/parallel switching equipment. The said chain connector has also a rectangular evenly spaced, linear hole pattern punched through each edge, with a moulded recess enabling the placement of a locking strip consisting of a strip of HDPE with moulded rectangular protrusions, which accurately complements the rectangular holes punched in the said chain connector.
h) Any combination of the said embodiments of the chain connector may be incorporated into a specific design as an individual project requirement.

The Floatation Pod: The resin/master batch mix may be blow moulded into a polygonal equatorial sectioned float with strengthening filleted edges, stabilizing round edge disk and a twist top with locking ribs:
a) The dimensions [i.e. its height] of the floatation pod can be varied to accommodate and provide stability for the payload and elemental force variation(s) (e.g.: wind and wave action).
b) The number of floatation pods/connection length can also be used as another option to provide extra buoyancy to the module cluster to support it and its payload;
c) The twist lock top is designed to slip into the chain connector bottom cutout ‘T’ section (c) above and twist lock fix [described later], into the bottom of the chain connector;
d) The number of floatation pods fixed into the chain connector can also be varied (as described above), to provide differential area specific buoyancy to the module cluster (and payload) to provide a gradient for water runoff. If for example the technology is used to completely cover a water storage body as required by The American Water Works Association Standards [AWWA Standards] together with the US Environmental Protection Agency Long Term 2 Enhanced Surface Water Treatment Rule [US EPA LT2 Rule] floating cover regulations.
e) Or in another embodiment the floatation can be incorporated within the design of the chain connector with either a fixed [hard] extrusion or a flexible inflatable bag attached or inserted in an extrusion, or extruded with the chain connector.

The Ballast Pipe Adaptor: The resin/master batch mix may be injection moulded into the part with strengthening filleted edges, stabilizing round edge disk and a twist top with locking ribs:
a) The dimensions [i.e. its height] of the said Ballast Pipe Adaptor can be varied to accommodate varied stability for differing payload types and elemental force variation(s) (e.g.: wind and wave action);
b) The radius of the ballast pipe flange can be varied to accommodate varied ballast requirements for differing payload types and elemental force variation(s) (e.g.: wind and wave action);
c) The adaptor includes three locking pins which slide into three linear equally spaced rectangular holes through the ballast pipe flange;
d) The said pins are used to fix the ballast pipe in place under the ballast pipe adaptor flange.

The Ballast Pipe: The resin/master batch mix may be extrusion moulded into the part:
a) The critical dimensions [i.e. its diameter and below water depth] of the said

Ballast Pipe can be varied to accommodate varied stability for differing payload types and elemental force variation(s) (e.g.: wind and wave action);
b) The ballast pipe has a pattern of equally spaced holes cut in two off centre parallel plane directions equidistant and parallel to the vertical plane through the central axis of the said pipe;
c) The said holes allow time limited ingress and egress of air and water into the pipe as a water ballast stabilizer;
d) There is also another equally spaced linear pattern of a group of three rectangular holes, which accurately complement the rectangular holes punched in the said ballast pipe adaptor flange, spaced at module length intervals, to accommodate the three ballast pipe adaptor pins;
e) The ballast pipe can have end caps included [if specified] and continuity adaptors between pipe lengths.
f) The ballast pipe continuity adaptors [standard manufactured pipe length connectors], are alternated for each flanking chain connector forming a stretcher type pattern.

The Floatation Bag/Balloon: The resin/black master batch mix may be blow moulded into a bag/balloon, with a semi-profiled reinforced top section, specific to its application. Each bag is air inflatable, with the main expansion specifically designed to match the interior shape and floatation requirements of each module type and application. The floatation bag can be serviced via removal of the access cap and access washer.

The Access Module: The resin/master batch mix may be injection moulded into a modular shell assembly of three main parts:
1. The Perimeter housing: This part has the same modular connections and dimensions as the standard module, while providing a flexible membrane barrier [or seal] to airborne water and particulates; it also provides a fixing frame for the internal floating platform.
2. The Internal Floating Platform: This part is connected to the perimeter housing via a membrane or skirt [inverse of point 1 above].
3. The first embodiment of this device is a bottomless [ie: without a bottom], sealed [air tight] rectangular box, with the capability to be fitted with up to four floatation pods to maintain its floatation.
4. In another embodiment the bottomless rectangular box has a sealable cylindrical hole in the centre top, with a screw thread in the said top. The said threaded cylindrical hole will accept a screw in closure mechanism to clamp the air bag washer which incorporates a hole to allow for the placement of a floatation bag with a [sealed] inflation access point through said hole.
5. The cylindrical fixing mechanism allows for quick and easy replacement or service of the floatation bag;
6. The Connecting membrane or Skirt [used in a total cover requirement]: This provides a flexible connection between the perimeter housing and the vertically moving floating platform. The movement [and floatation] of the said platform provides a floating payload capacity of about 200 Kg and therefore walking access over the water body, for service, maintenance and breakdown repair;
7. In another embodiment where a total cover is not required, the central moving part incorporates articulated flaps which cushion the impact of the return of the central part to its original position against an appropriately chamfered protrusion.

Advantages of this invention include::
a) The modular shell assembly procedure will produce long chains or strings of connectable modules which are easily deployed;
b) The module chains or strings may be connected via the chain connector extrusion in a compression ‘clicking’ procedure, which can be locked, enabling the assembly of virtually any cluster size;
c) The modular shell can be specifically designed to support any type/style of PV Panel payload superstructure;
d) Each chain connector is bypassed when off line due to shadow or fault, however, the voltage and current is still monitored and is automatically switched online when the programmed operational levels are attained, unless the said connector is shut down manually;
e) The chain connector bypass system can be manually engaged for service and/or inspection;
f) The online chain connectors are connected in series [via the terminal connector] until the required system voltage is achieved and there is therefore a system redundancy;
g) The single and multiple cluster size is designed/standardized to the inverter capacity;
h) Multiple clusters can be automatically linked [via PLC control] during low light [low power] events to lower power generators, expanding diurnal power production duration;
i) The dimensions and number of floatation pods [and floatation bag volumes], can be specifically varied according to the specified wind/wave load and payload factors;
j) This specific connectivity and generic tethering inserts of the module and chain connector deployment enables the incorporation of active positional control as well as single axis sun tracking for any type of photo-voltaic [PV] power generating device;
k) The module clusters can be reinforced with insertions;
l) The patterning and position of the inserts can be varied according to site specific wind and wave conditions;
m)Free floating [insert reinforced] perimeter clusters can be used [with framing] to support single axis circular sun tracking sub-clusters;
n) Free-floating [insert reinforced] perimeter clusters can be used for PV payload as well as booming;
o) The deployment can be moved [floated] in its entirety whilst continuing to function and positioned on a flat ‘shelf’ adjacent to one or more storages, allowing cleaning and maintenance of the drained storage to be completed;
p) Advances in PV thin film technology [PVTFT] efficiencies and application techniques will allow further simplification of the PV Panel and superstructure, where the PVTFT can be embedded/laminated in the exposed surface of the module(s). Using the chain connector as the preferred connecting mechanism.

### DETAILED DESCRIPTION OF THE INVENTION

A preferred embodiment of the invention will be described with reference to the drawings which:

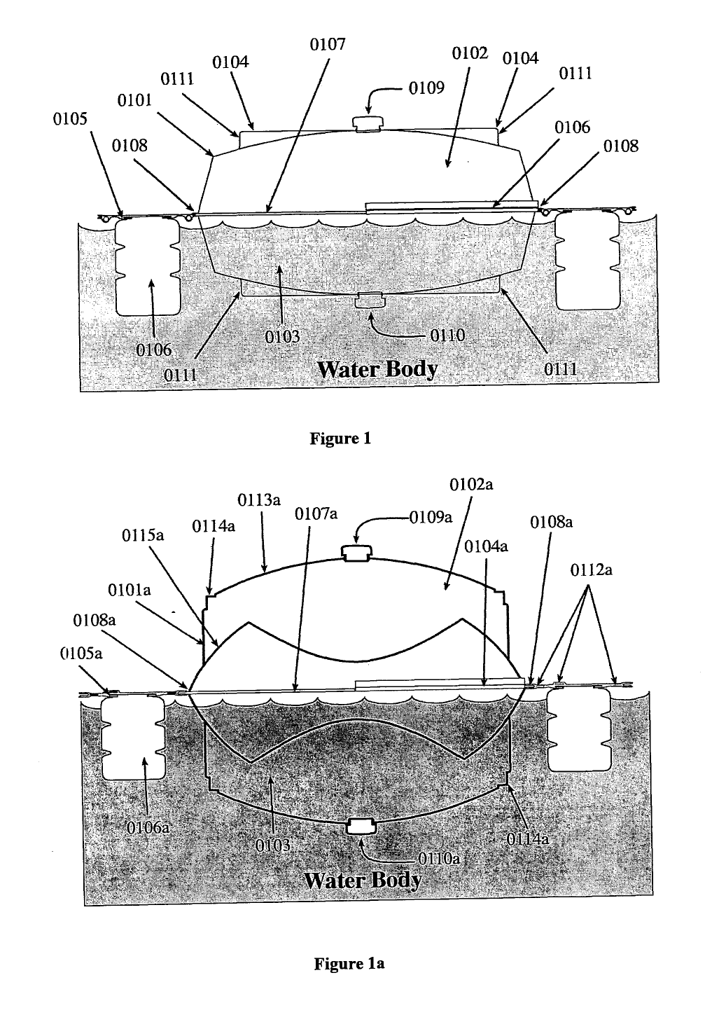

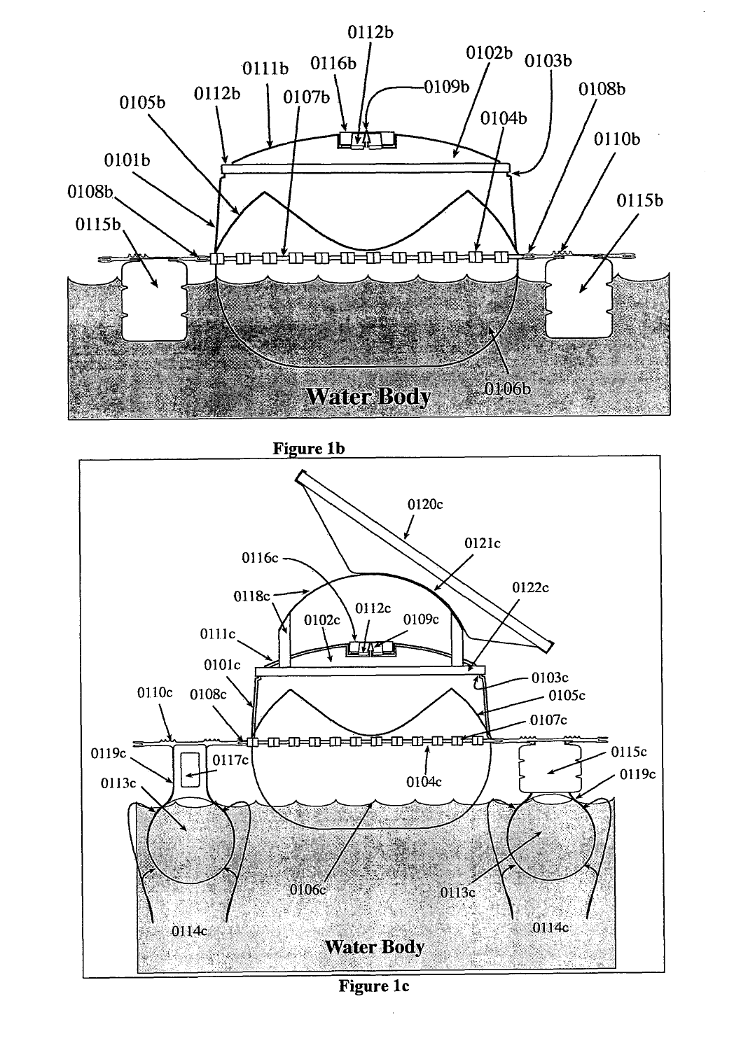

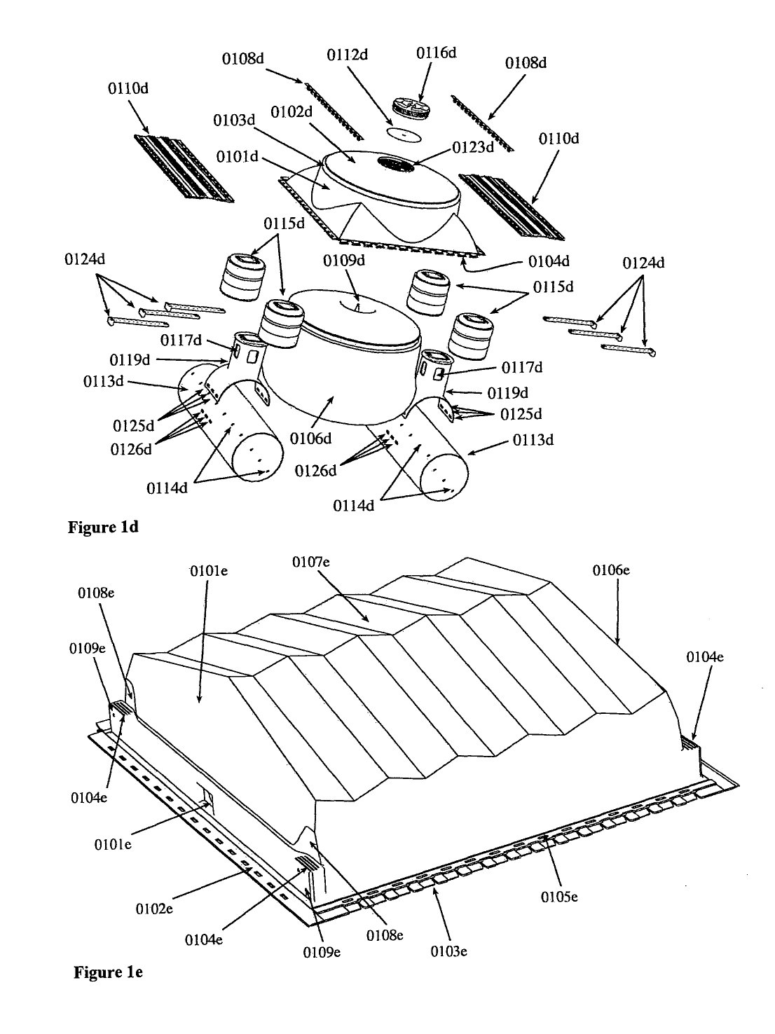

FIG. 1 illustrates a sectional view of the assembled module with attached chain connectors, floatation pods and light extinction caps;

FIG. 1a illustrates a sectional view of the preferred module with attached chain connectors, floatation pods and light extinction caps;

FIG. 1b Illustrates a sectional view of the preferred module with attached chain connectors with a floatation balloon;

FIG. 1c Illustrates a sectional view of the preferred module with attached chain connectors with a single floatation balloon, one floatation pod, two ballast pipe adaptors with pins, two ballast pipes and the PV panel and superstructure;

FIG. 1d Illustrates an exploded view of the preferred module with attached chain connectors with two locking strips, a floatation balloon, four floatation pods, two ballast pipe adaptors with pins and two ballast pipes;

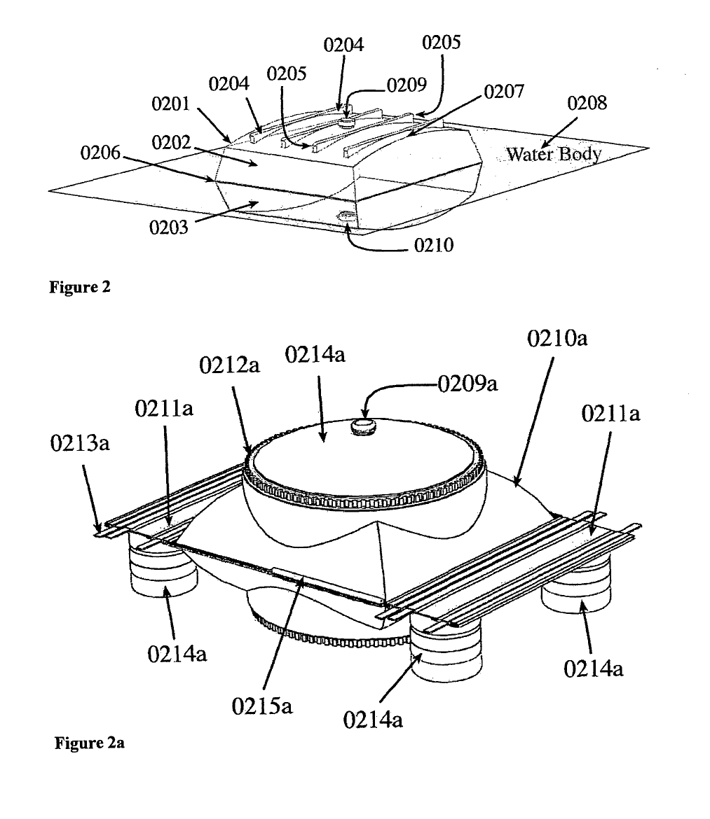

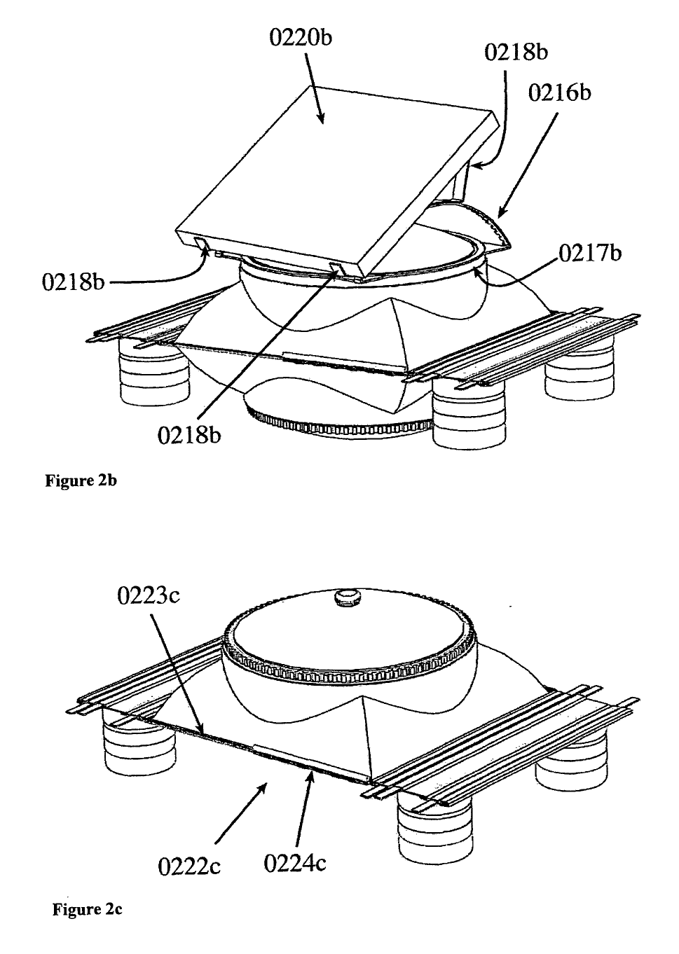

FIG. 2 illustrates an isometric drawing of the assembled module [above] without chain connectors and floatation pods;

FIG. 2a illustrates an isometric drawing of the preferred module with chain connectors and floatation pods;

FIG. 2b illustrates an isometric drawing of the preferred module with chain connectors, floatation pods and PV payload;

FIG. 2c illustrates an isometric drawing of the preferred top shell with chain connectors, floatation pods and no bottom shell;

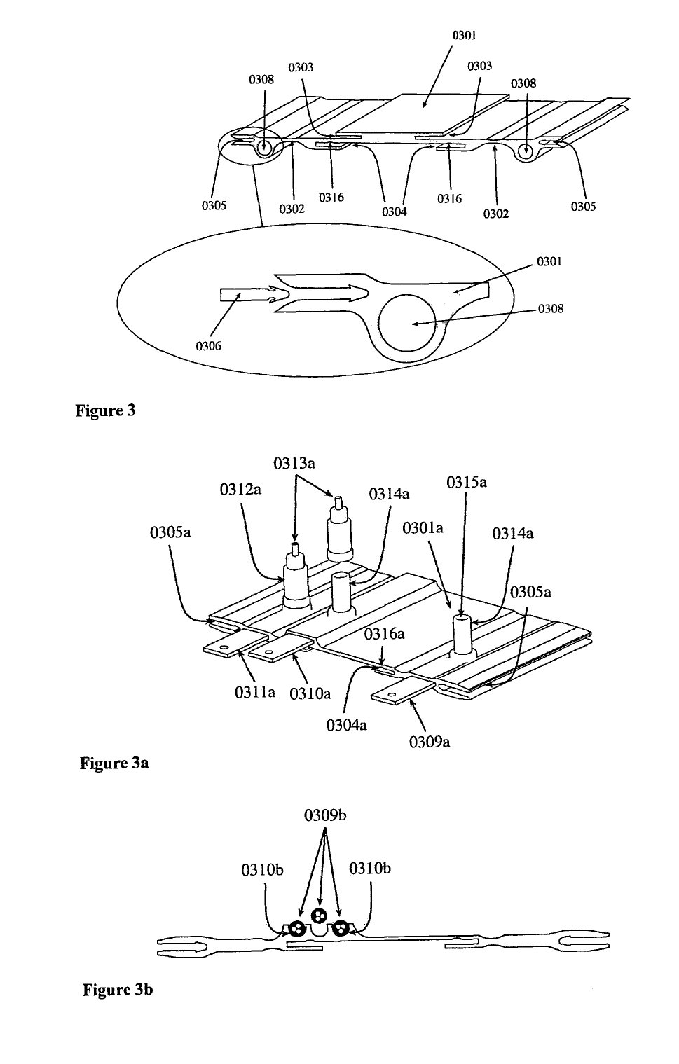

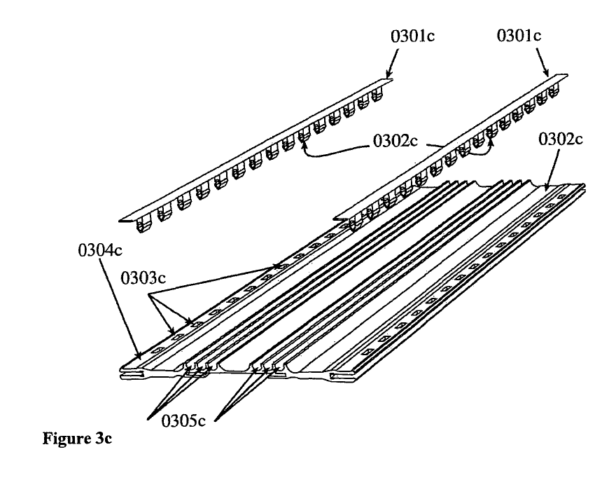

FIG. 3 illustrates an isometric drawing of the chain connector;

FIG. 3a illustrates an isometric drawing of the chain connector with bus bar inserts and power input connectors;

FIG. 3b illustrates a sectional drawing of the chain connector with press fit circular cable extruded receptacles replacing the solid copped [or other] bus bars;

FIG. 3c illustrates an isometric drawing of the preferred chain connector with six press fit circular cable extruded receptacles replacing the solid copped [or other] bus bars and the two removable locking strips;

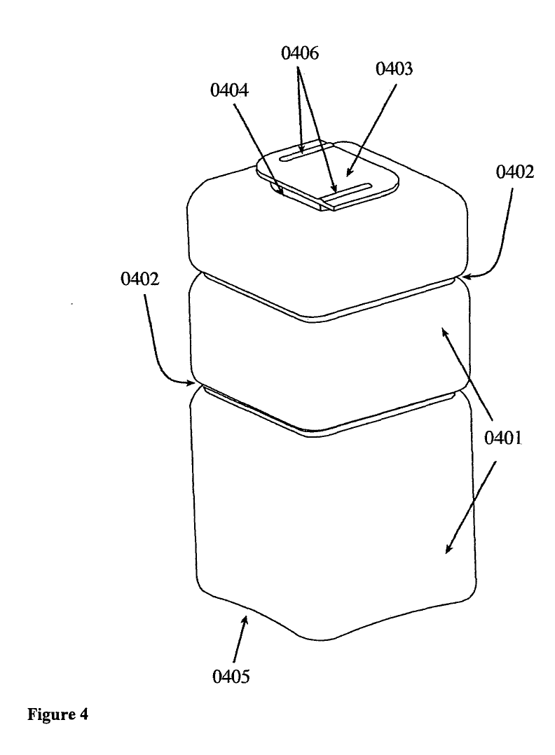

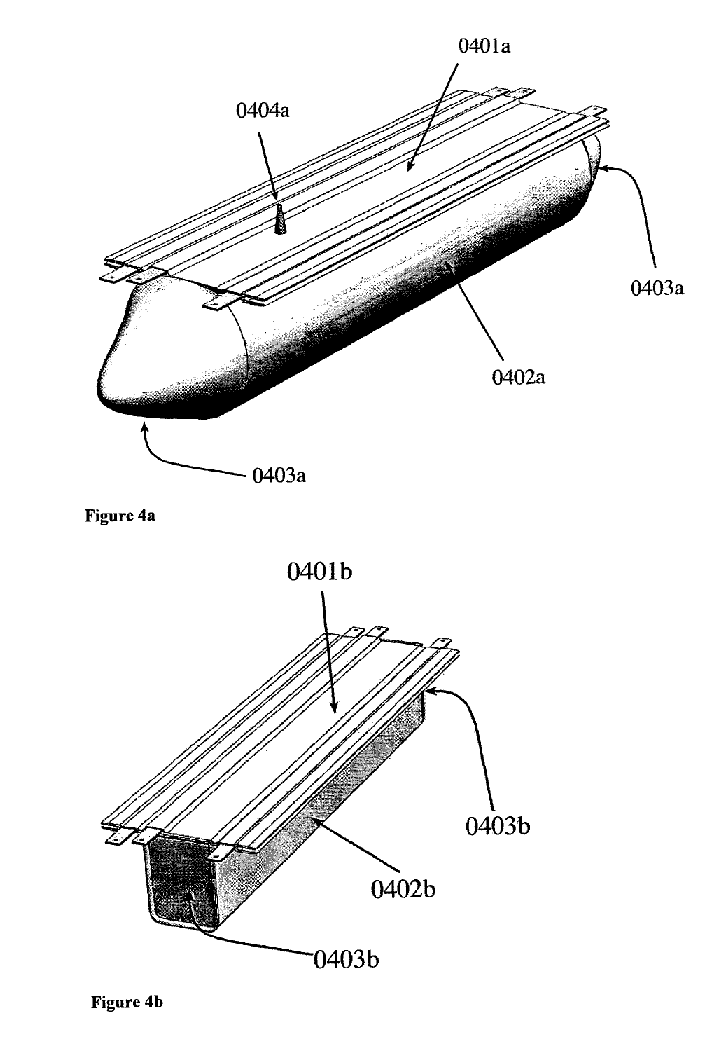

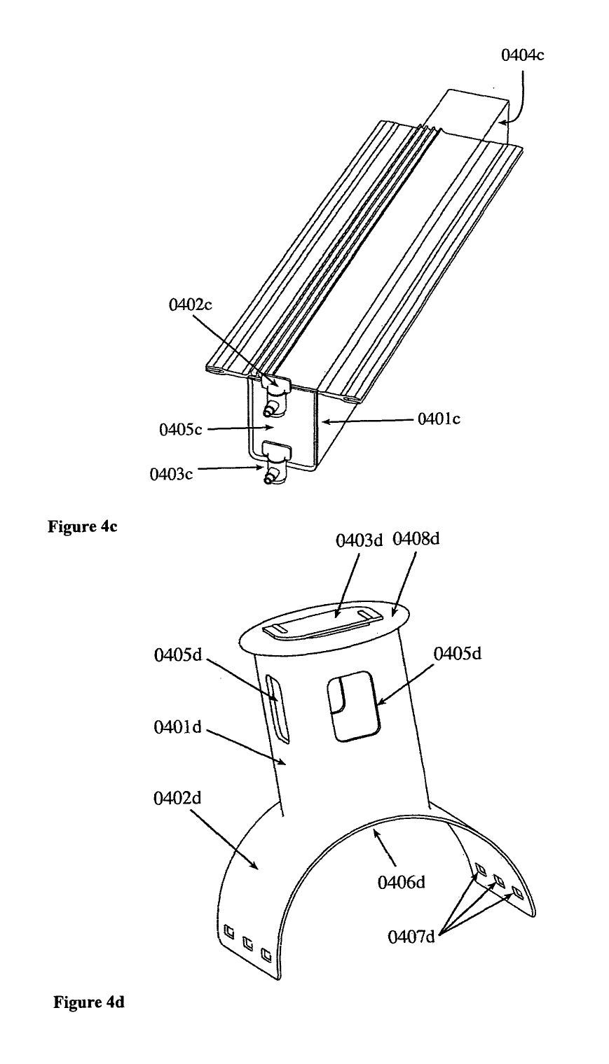

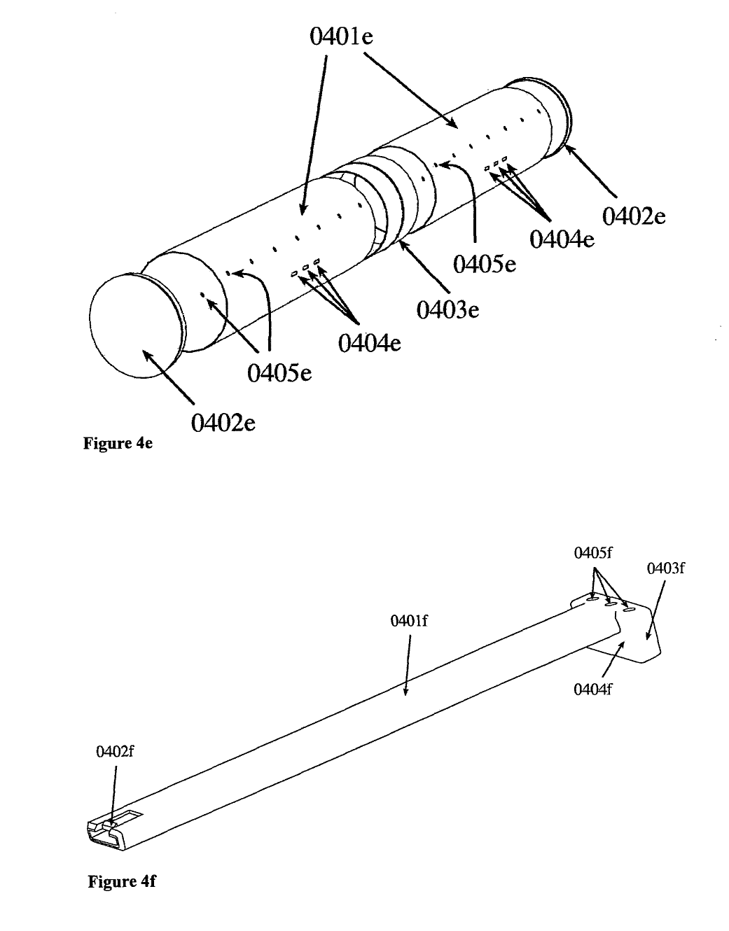

FIG. 4 illustrates an isometric drawing of the floatation pod;

FIG. 4a Illustrates an isometric drawing of an amalgamation of both the chain connector and floatation pod concepts, where the chain connector is extruded together with a flexible and inflatable polymer bag below the chain connector or, extruded with a solid section that can accept one or more polymer inflatable bags.

FIG. 4b illustrates another drawing of an amalgamation of both the chain connector and floatation pod concept, this embodiment entails a polygonal solid extrusion below the chain connector with the addition of end caps;

FIG. 4c illustrates a drawing of an amalgamation of the chain connector and ballast concept, this embodiment entails a polygonal solid extrusion below the chain connector that can be extended to any length, with the addition of end caps and taps to insert the required liquid ballast;

FIG. 4d illustrates an isometric drawing of the ballast pipe adaptor;

FIG. 4 illustrates an isometric drawing of the ballast pipe with end caps and extension adaptor;

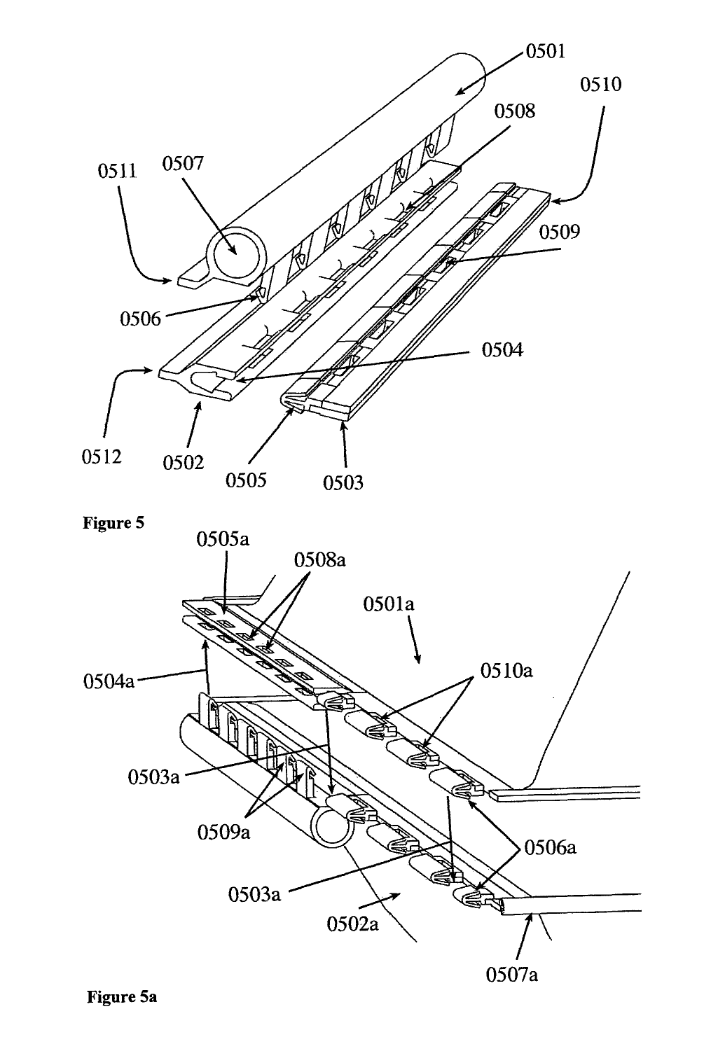

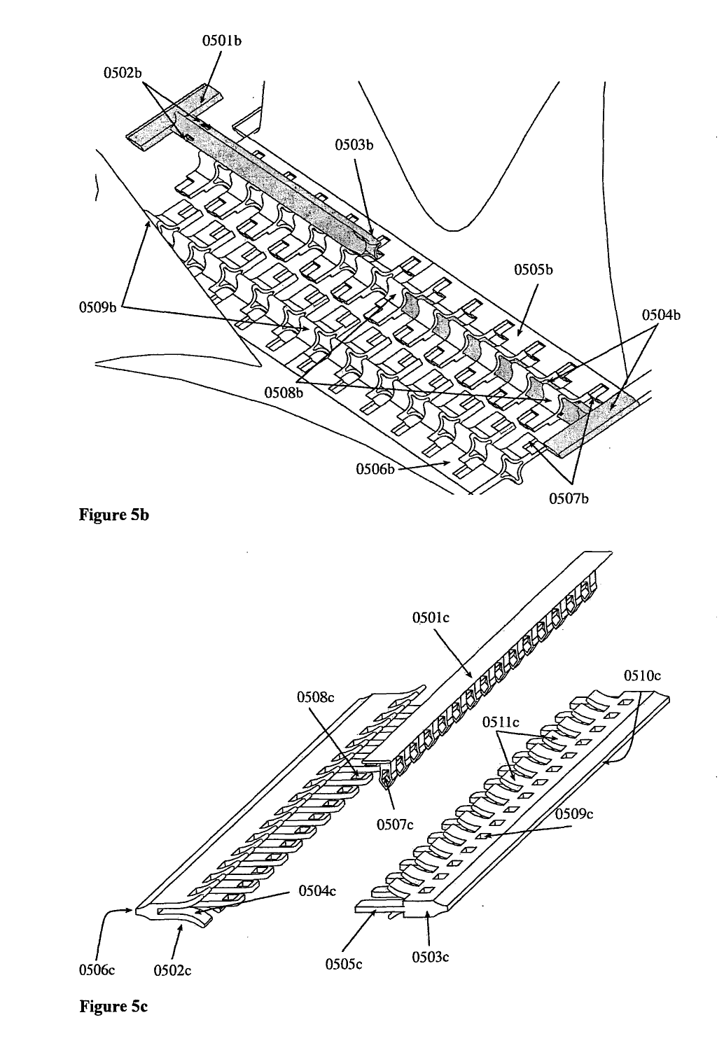

FIG. 5 illustrates an explosion drawing of a module shell connector locking assembly;

FIG. 5a illustrates an explosion drawing of another view of the above module shell coupling assembly;

FIG. 5b illustrates an explosion drawing of another module shell coupling assembly and two locking pins;

FIG. 5c illustrates an explosion drawing of the preferred module shell coupling system;

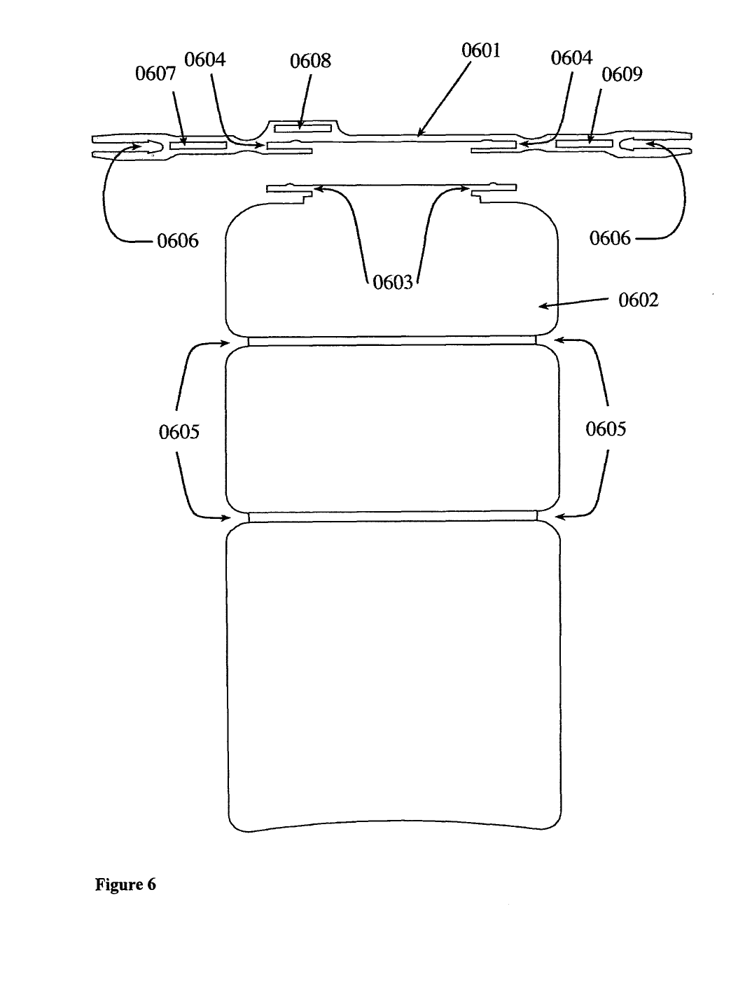

FIG. 6 illustrates a sectional drawing of the preferred chain connector and the floatation pod;

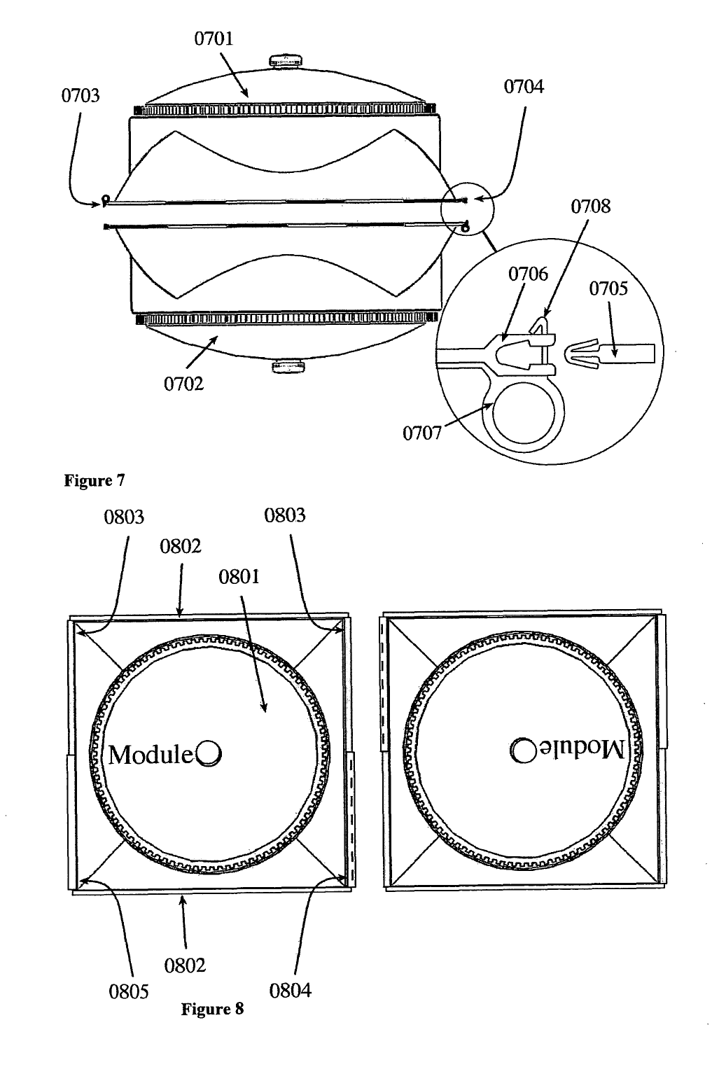

FIG. 7 illustrates a sectional drawing of the module shell inversion and mating procedure;

FIG. 8 illustrates a plan view of the module rotation and chain coupling procedure;

FIG. 9 illustrates two module cluster types;

FIG. 10 illustrates a terminal connector support module with the chain connector bending from the horizontal to the vertical;

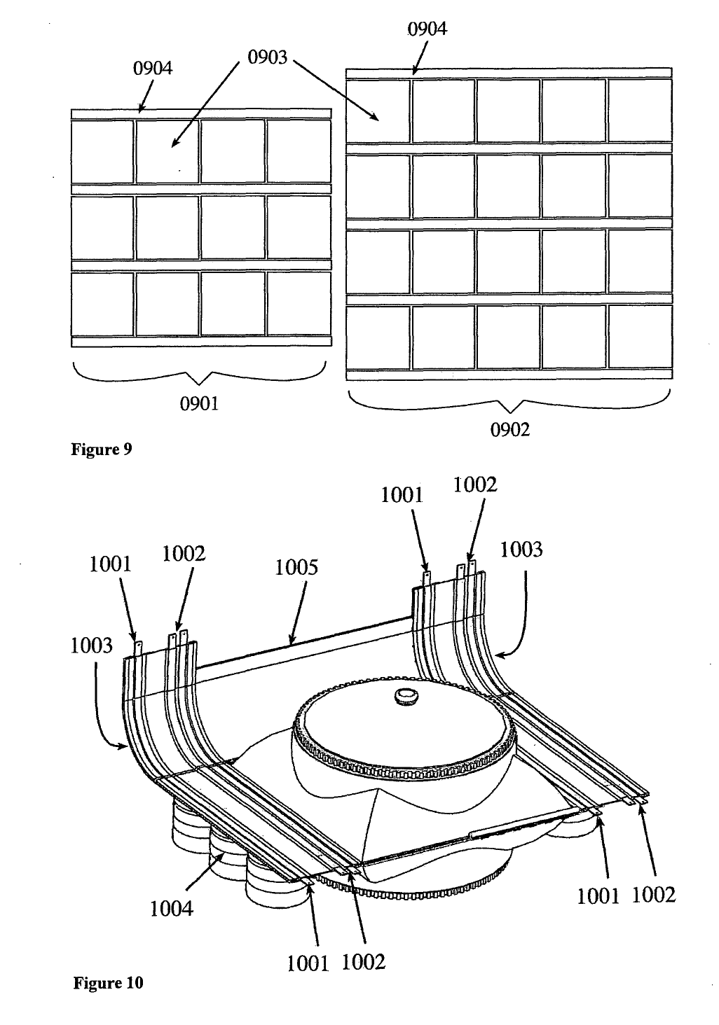

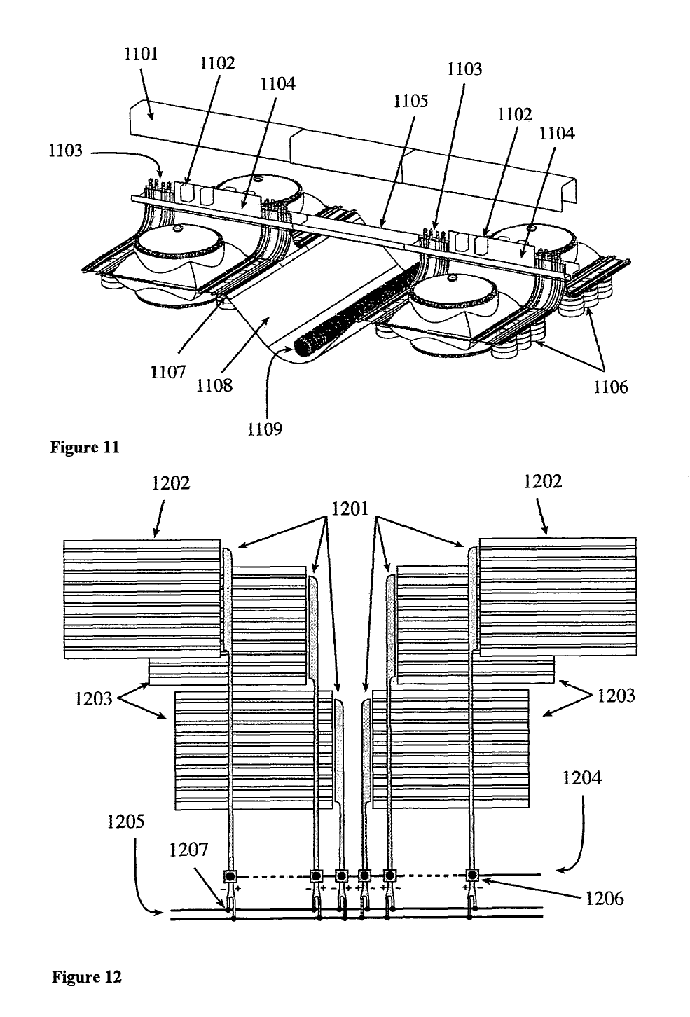

FIG. 11 illustrates two pairs of terminal connector support modules with the chain connector bridging over a gutter containing a drainpipe. This type of bridge is used to span between clusters.

FIG. 12 illustrates diagrammatically the concept of switching any cluster combination in parallel [note: clusters displaced for illustration purposes only];

FIG. 13 illustrates a schematic electrical circuit diagram of a single cluster;

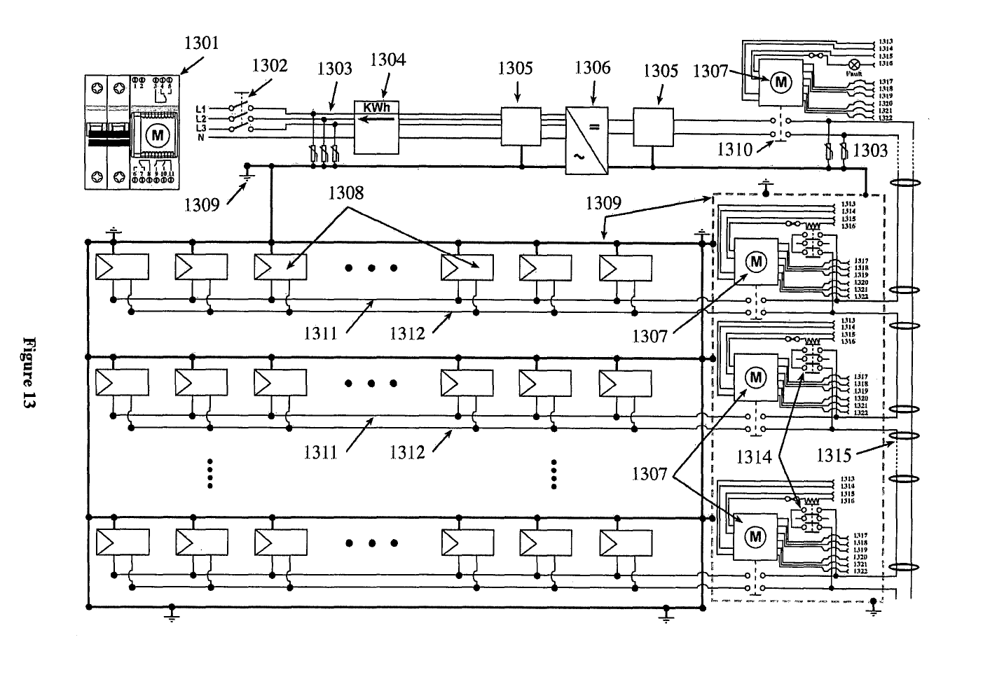

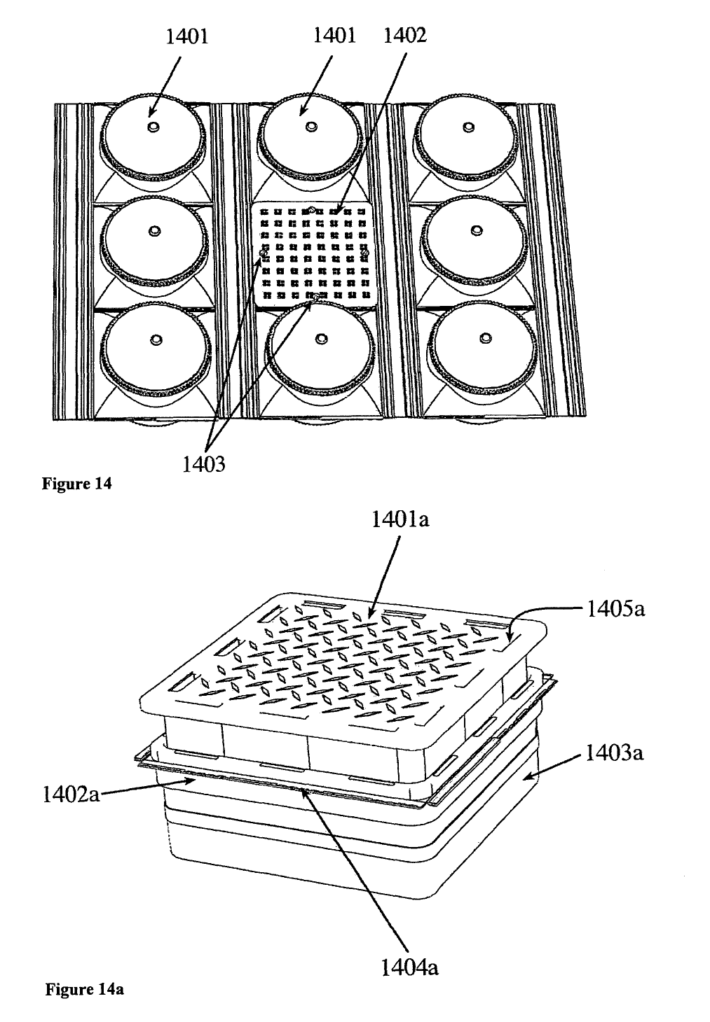

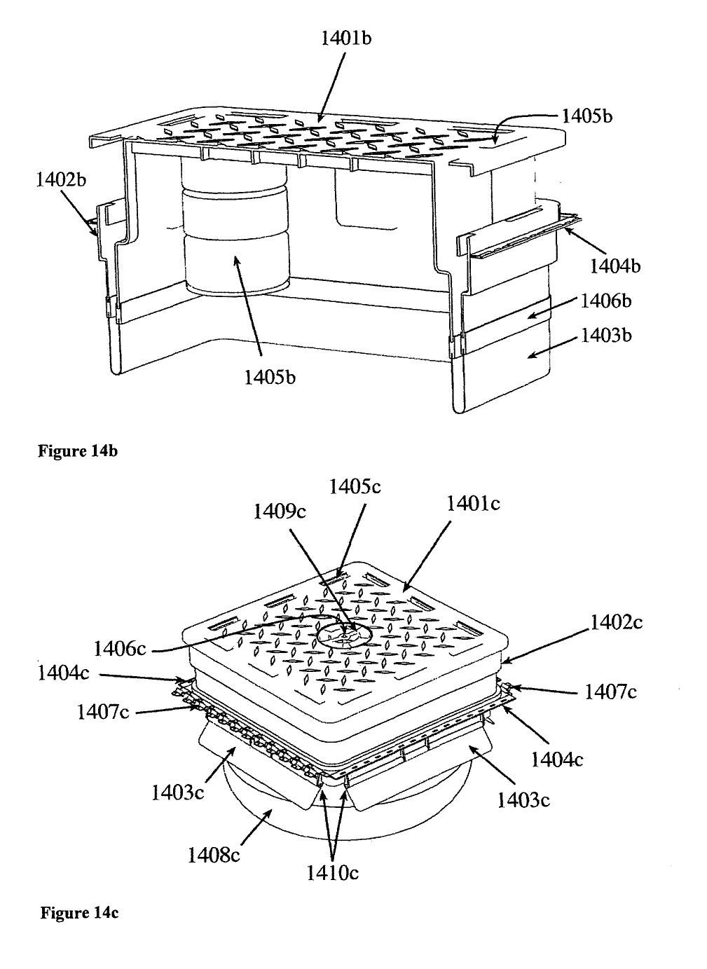

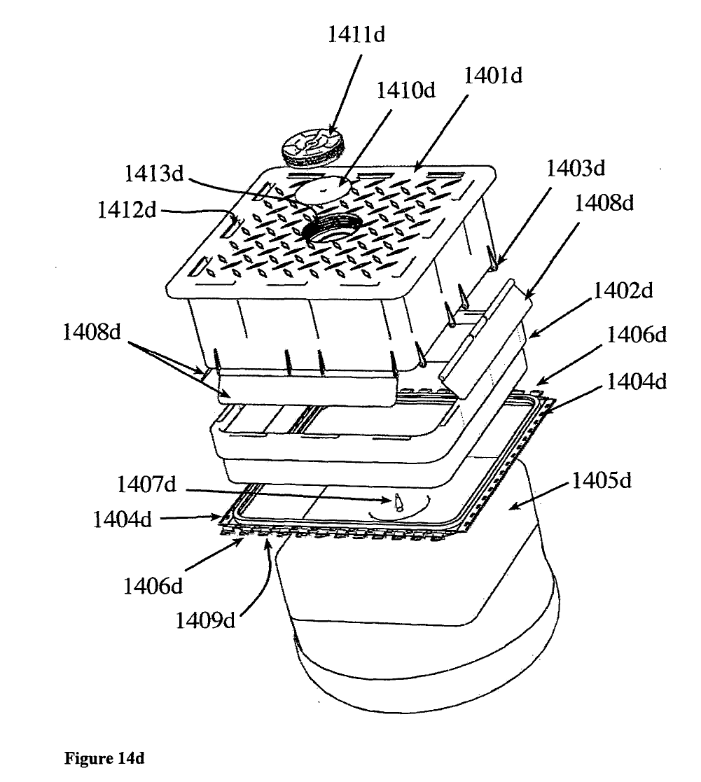

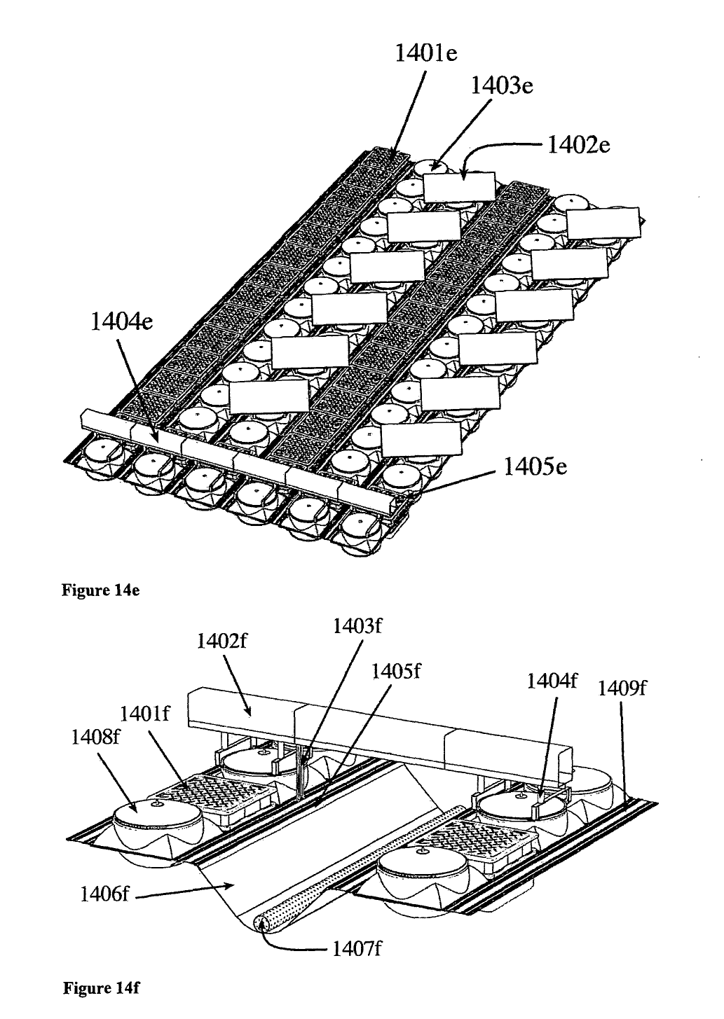

FIG. 14 illustrates a modular divers hatch integrated into a 3×3 module array. Note that system sumps are also modularized;

FIG. 14a illustrates the first embodiment of the Access Module top view. The access module provides servicing and repair access to key parts of the system deployed on the water body;

FIG. 14b illustrates a sectional view of the said access module;

FIG. 14c illustrates a top view of the second embodiment of the access module;

FIG. 14d illustrates a explosion diagram view of the said second embodiment;

FIG. 14e illustrates the access module and its use in deployment;

FIG. 14f illustrates a terminal bridge across a gutter between modules with the balloon floatation embodiment. The figure illustrates the use of the gutter pipe and its contents [if any], with the water in the gutter as a ballast [weight], for the deployment;

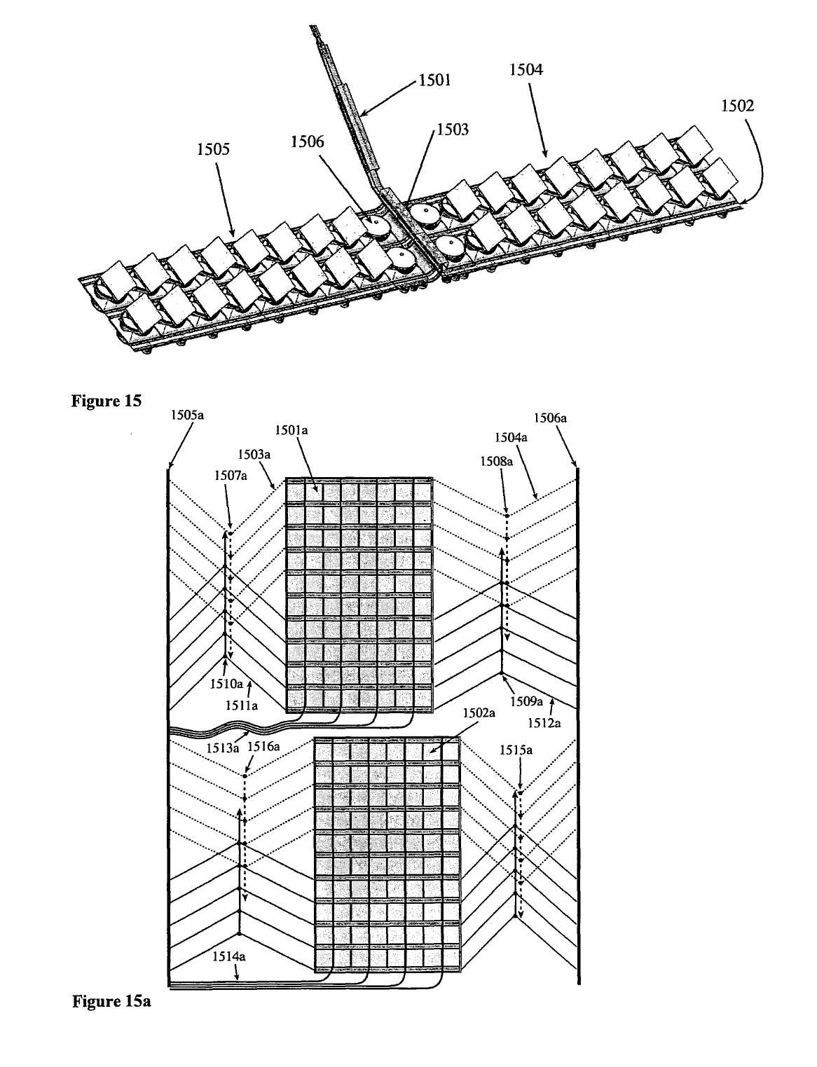

FIG. 15 illustrates two 9×2 clusters connected back to back to the terminal connector with an attached hinged gantry;

FIG. 16 illustrates several circular module clusters pivoted on a central axis with controlled tethering;

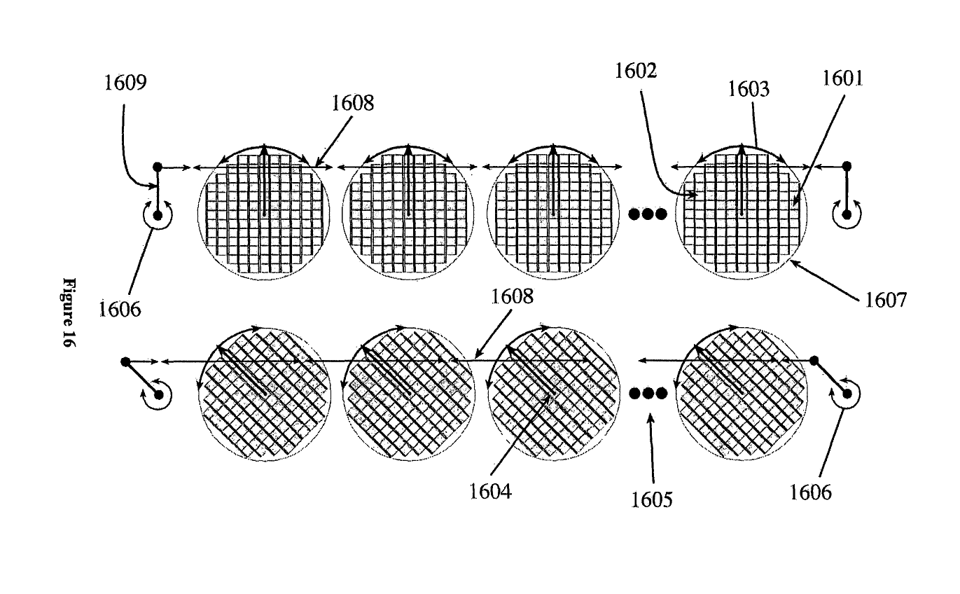

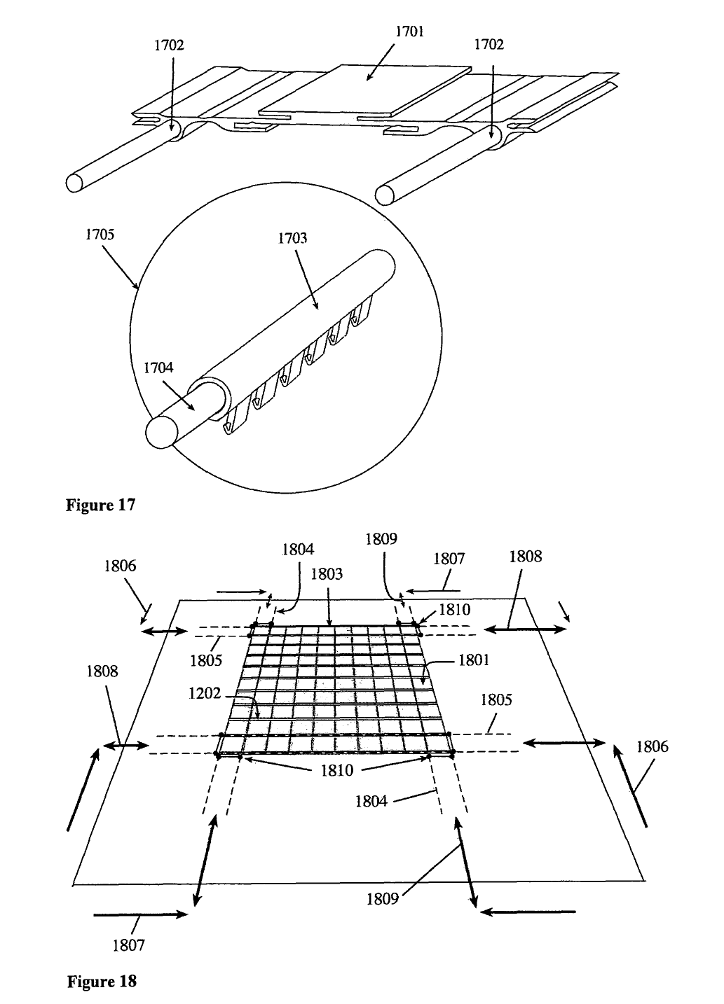

FIG. 17 illustrates the chain connector and module chaining lock with tethering inserts;

FIG. 18 illustrates a 10×10 module array with tethering allowing controlled movement of the array over the water body;

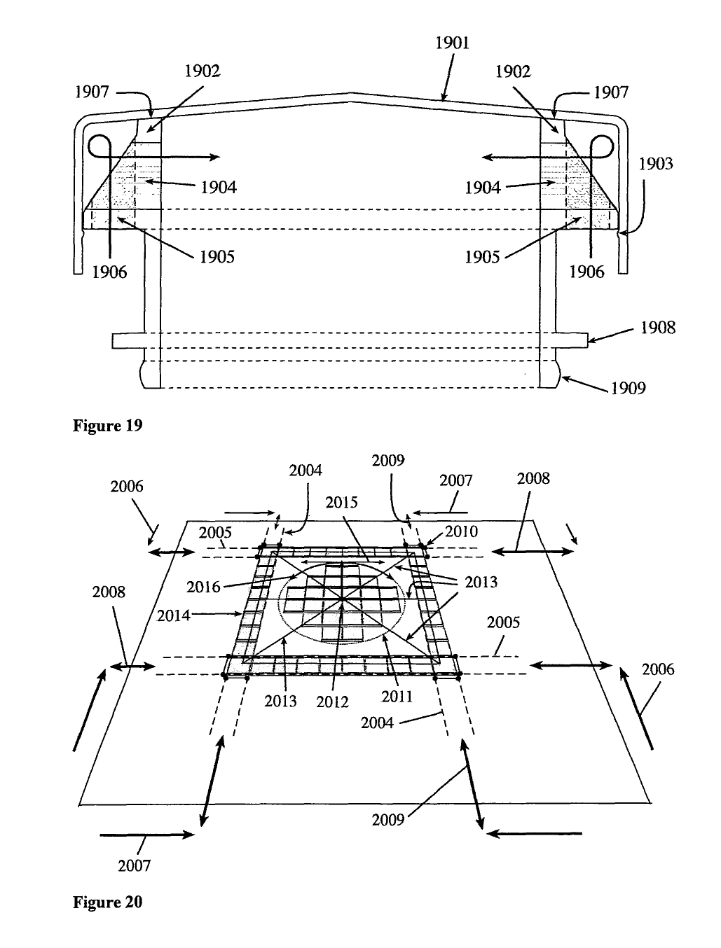

FIG. 19 illustrates a sectional view of the light extinction cap

FIG. 20 illustrates a 24 module cluster supported via a 10×10 single module square perimeter cluster;

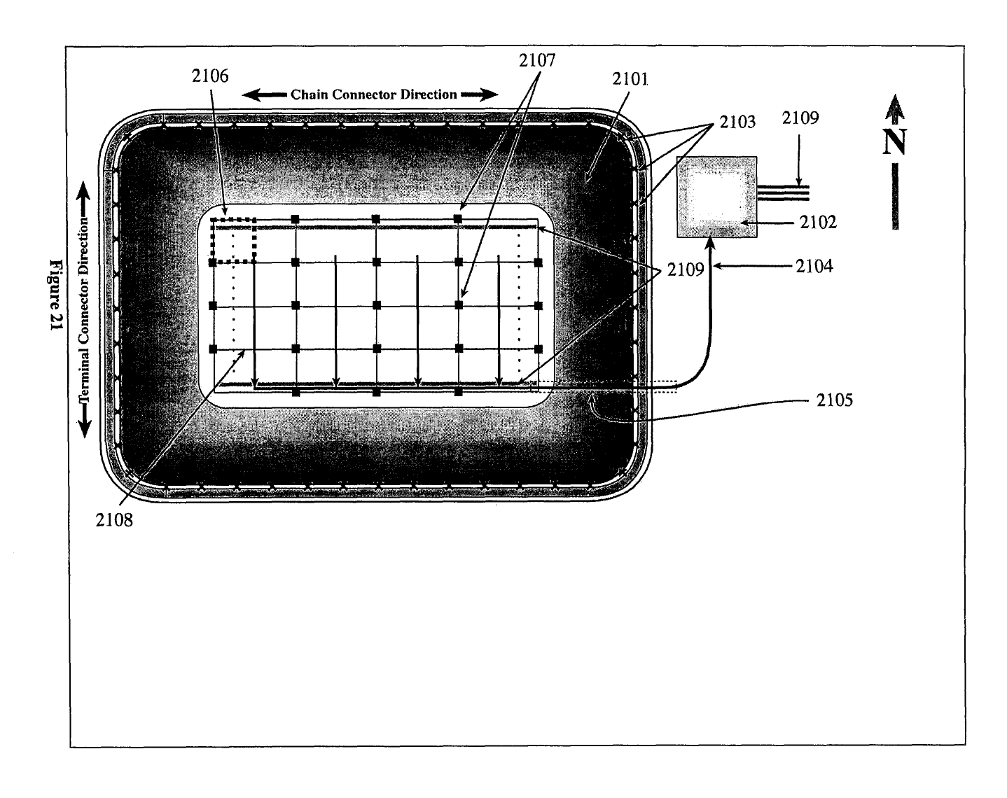

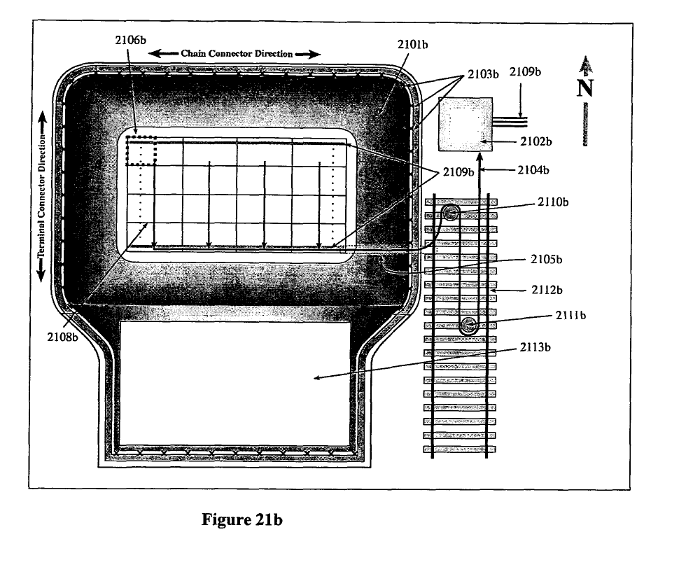

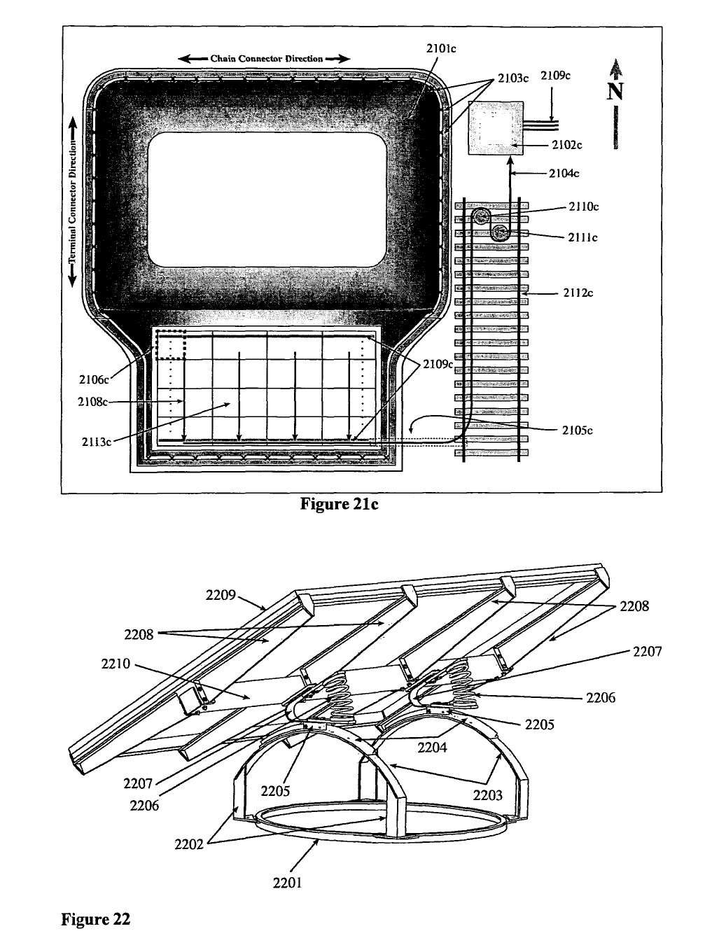

FIG. 21 illustrates a typical deployment of 32 clusters on a rectangular water body;

FIG. 21b illustrates a typical deployment of 32 clusters on a rectangular water body with a parking shelf;

FIG. 21c illustrates a rectangular water body with a typical deployment of 32 clusters moved onto the parking shelf;

FIG. 22 illustrates an isometric drawing of the PV Panel support superstructure which includes a dual spring articulated tilting system of which the spring constant can be specifically designed to activate [tilt] when subjected to a specific site determined wind loading threshold.

The first preferred embodiment of the module shell [see 0101 and 0201] and the second embodiment [see 0101a, 0210a, 0111b, 0701 and 0801], (the Turret Module), is injection moulded in a standard multiple ‘shot’ process. The shell has a square equatorial hollow section [0206, (preferred 0105b and 0210a)], tapering to a slightly curved top [0207], tapering vertical walls [0102, 0103 and 0202] or, in the second embodiment tapering into a vertical cylindrical section [0115a and 0210a], with a dome top [0113a and 0214a]. The vertical cylindrical has a taper [0101b], sufficient to allow close pack stacking of the shells for transportation.

The curved top [0207] of the first embodiment has moulded ribbing [0104 and 0204] to enhance the strength [for payload support] and provides recesses at each end of the ribs [0111 and 0205] providing fixing points for the payload support structures. Whereas the second embodiment includes a dome top [0113a, 0111b, 0102d and 0214a] and a specified arc length, of slotted strengthened perimeter [0114a and 0212a]. Each slot is 4° wide and provides a 4° fixed increment horizontal alignment for the module [PV or other] Payload [0217b and 0220b respectively]. This perimeter has a recess [0103b] to allow solar collector clamping mechanisms to fix to the head of the shell. The size/design of the clamping mechanisms and the corresponding recess can vary according to the site wind loading specifications.

In another embodiment moulded slots [0104e] accept PV support arms, which are fixed to the module shell with bolts inserted through moulded holes [0109e]. This embodiment has a reinforced polymer arm structure parallel to the chain connector strip [0102e] thereby reducing the complexity of the PV support superstructure [and assembly], by integrating a part of it into the module shell.

The edge connectors [protruding outward from the square base] of the said module embodiments can have several alternatives. In one embodiment two opposing sides of the base [0108, 0108a and 0802] have arrowhead connectors [0108, 0108a and 0108b] with vertical sections [0306, 0505 and 0705] for connection to the chain connector [0301, 0301a and 0601]. The other two opposing sides [of the module] have a combination of male arrowhead connectors [0107, 0107a, 0505+0503, 0506a, 0705 and 0803] with slots [0508, 0509, 0508a and 0510a] and a corresponding female receptacle [0502, 0505a, 0706 and 0804] on one and the other a male arrowhead and locking device [0506, 0509a and 0707].

Each shell is designed so that when two shells are properly oriented [0701 and 0702] and mated at the base to form a module 0503a. They have the capability to lock together as shells [0706, 0707, 0509a and 0505a] and also with other modules [mated shells] in series [via the parts 0501, 0502 and 0503] ad infinitum, to form modular chains [or strings].

Each module [see FIG. 8] when added to the chain, must be rotated through 180° to align the appropriate receptacles for mating. In the mating process [as the two shells are brought together], part [0501] and the attached catches [0506], which is attached to the module shell [0805], are prevented from entering the locking receptacles [0508] via an inserted bar into [0507] until the next module [chain link] has mated [0503, 0705 and 0803] with the female receptacle [0502, 0706 and 0804]. Once mated the lock [0501, 0707 and 0805] is allowed to close [0707 and 0706].

Note that: The top shell can be connected to the chain connector [and in a cluster array] without a bottom shell [0222c], i.e.: without a ballast without inhibiting the module chain connection process [0223c & 0224c].

In fact if elemental, payload, superstructure and deployment conditions are favorable, and deployment costs an issue, half shelled modules may be deployed in entire clusters.

Floatation is provided with the use of floatation bags [0106b, 0106c and 0106d]. The on water stability of such an array is provided with the use of ballast pipes [0113c and 0113d] suspended below the chain connector. The ballast pipes are perforated with small holes [0114c and 0114d] to allow [limited but] sufficient ingress and egress of water. The ballast pipes also act as stands for the array when floated out onto a dry dock. More on water stability can be achieved by adding extra floatation pods to the chain connector [0115b, 0115c and 0115d]. A ballast pipe adaptor connects the ballast pipe to the bottom of the chain connector.

The floatation bag is designed such that its main expansion propagates from the bottom section.

The flotation module [incorporating two shells], has a vent (hole) centrally placed on top of the top and bottom shell to ingress and egress of air and water respectively. The top vent can preferably be fitted with a light extinction cap [1901, 1904], which will allow the ingress and egress of air, but exclude light. By excluding the light from the upper module, algae incubation within the module is eradicated. The cap consists of two parts the top [1901] and the insert [1904]. The cylindrical insert has a barb at the base [1909] and a flange [1908] for push and click insertion. At the top the inset has a triangular toroid formed on the outside of the cylinder. The toroid has two sets of non-connecting radial slots [1904 and 1905] of 0.5 mm width perforating through two of its sides. The first set of radial slots cuts vertically from the base of the triangular toroid through to the hypotenuse, the second set of slots cuts horizontally from the hypotenuse through to the centre of the cylinder. The cap when placed on the insert forms a light tight seal via [1907] and the barb [1903]. Air can ingress and egress in the path illustrated by [1906], with the exclusion of light. The chain connector and any other part of the deployment can be vented [if needed] via the said light excluder.

Two or more long chains of modules formed using the chain lock [FIGS. 7 and 8], can be connected via the chain connector [0105, 0105a, 0211a, 0301, 0301a, 0601, 1502 and the clusters FIG. 9 and FIG. 14]. During the module mating process the male arrowhead side connectors [0108, 0505, 0507a, 0705 and 0802], of the modules are mated. The combined mated profile can now be inserted via [0306 to 0305] into the chain connector [0305], in a compression ‘click’ procedure. The chain connector also has provision for payload frame support clips [0303], tethering inserts [0308] (discussed later) and a twist fix slot for the floatation pods [0304 and 0604] with a locking receptacle [0316, 0316a]. Note that: The floatation pod has a corresponding locking protrusion [0406]. The connector has engineered flexing lines [0302], which allow the module deployment defined movement parameters.

The module, chain connector and floatation pods can be connected into a cluster [1202, FIGS. 9, 14 & 15], and this structure can support a payload [FIG. 15]. Each module has the capacity to hold a [water] ballast [except the balloon/bag embodiment, see FIGS. 1b, 1c and 1d], which over a large deployment can become a significant volume [and therefore a body containing significant inertia] and is instrumental in keeping the deployment stable on the water body in the duration of storm wind and wave action. The ballast may be adjusted to endure most storm events.

The equator of the module [0206] is preferably kept 20-25 mm above the still water level [SWL]. To achieve this for a given payload, a calculated number of floatation pods are inserted into the chain connector to provide the buoyancy due to weight and any other elemental loading [e.g.: wind]. The size and design of the floatation pods can be varied to suit the specified requirements. For example: Larger loads may require longer and wider pods, or the pod profile may need to be varied to allow for ‘step’ floatation where the floatation pod is widened to provide an instantly large buoyancy beyond which requires a much larger loading to submerge.

Loaded polygonal chain connectors [FIG. 4c], and gutter pipes [1407f], with content, together with water in the system drain [1406f] and the system payload loads, will provide the necessary stabilizing [weight] ballast.

There may also be a requirement for specific falls within the module cluster itself, such as under: AWWA Standards, for US TL2 Cover, in this case the number of floatation pods per standard chain connector length can be varied to realize the specification.

Another embodiment of the chain connector is realized in the amalgamation of both the chain connector and floatation pod concepts, where the chain connector [0401a], is extruded together with a flexible and inflatable polymer bag [0403a] below the chain connector or, extruded with a solid section [0402a] that can accept one or more polymer inflatable bags. Varying the inflation [air content] of the bag [via air valves [0404a] will correspondingly vary the floatation of the module/module chain.

In a further embodiment the polygonal solid extrusion [0402b] is extended below the chain connector [0401b] and is sealed with the addition of end caps [0403b].

Floatation variance in this device is achieved but the specifically designed volume of the floatation chamber and finer adjustment of the floatation achieved via controlled water ingress through inlet/outlet valves. This said chain connector can be used with the floatation balloon/bag embodiment as a ballast stabilizer for varying elemental/payload conditions.

In the case of high wind speeds for long durations, floatation problems are alleviated via the balloon/bag embodiment, where the actual size of the balloon floatation exceeds that achieved via the floatation pods and in addition, internal pressures of the bag/balloons can be varied dynamically to achieve the required floatation.

Integrity on the water body is obtained the use of ballast pipes [0113c, 0113d and FIG. 4e]. The ballast pipes are suspended below the water level via the ballast pipe adaptor [0119c, 0119d and FIG. 4d]. This said ballast pipe adaptor is fixed to the bottom of the chain connector using a hysteresis shaped twist lock [0403d], used to fix it to the chain connector identical to the floatation pod [FIG. 6]. The said fixing point also includes a lateral torque disk [0408d], improving the lateral strength of the fixing point.

This embodiment type is the preferred option for all deployments exposed to elemental conditions.

The floatation pod has reinforcing moulding [0402, 0405 and 0605] to enhance its strength and a hysteresis shaped twist lock [0403, 0603], used to fix it to the chain connector [FIG. 6].

Another embodiment of the chain connector [FIGS. 3a, 3b, 3b, 0601 and 1502] includes insertion of three [circular, rectangular] copper bars, of sufficient cross-sectional area to provide a low Voltage loss to the transmission of electrical current through them. One of the three copper bars [0309a, 0309b, 1001 and 1309] will serve as the surge and static electrical ground, whilst the other two will carry positive [0311a, 1311] and negative [0310a, 1312] DC Voltages [and currents]. The PV Panels are connected to the chain connector via insulated plugs [0312a] and sockets [0314a].

The socket conductor is pressed into the conductor, and insulated from the elements via a polymer outer sheath with internal water proofing gel cavities.

For specifications of low voltages in close proximity to the water body, this Chain connector embodiment connects all the PV Panels in parallel [1308] so that the maximum voltage across the conductors will be the maximum panel DC voltage which is low and safe to work with.

Motorized circuit breakers [1301, 1307], with isolating breakers [1314], that can be manually locked in the off position, for PV panel service and inspection, connect the chain connector electrical outputs in series with the other chain connector outputs at the terminal connector [1102, 1315, 1501 and 2105]. To connect to the terminal connector, the chain connector is bent from the horizontal position to the vertical position [1003], to a height well above still water level [SWL]. The bus bars are now in the vertical position [1001, 1002 and 1103], to facilitate cable connection and jointing insulation.

In the preferred embodiment [FIG. 3b], circular cables are pressed into extruded recesses [0309b, 0310b and 0305c], for connection to the terminal connector [1402f], the circular cables are bent out of the chain connector to the vertical position and extended to penetrate the floor of the terminal connector [1403f]. The said cables are then lugged and connected into the electrical circuitry. This embodiment is more economically feasible and provides less complexity in assembly and production than the previous embodiments.

The function of terminal connector is to rout cabling from each deployed cluster [1201, 1513a, 2104, 2104b and 2104c], to the substation [2102, 2102c and 2102c], well above the storage water level [FIGS. 1b & 1c], as well as providing a platform to mount electrical switchgear [1102] to minimize the cable number.

When a particular chain connector output is off line, it is bypassed and isolated from the terminal connector voltage, via bypass contactors [1314] encased in waterproof boxes [1102] on the terminal connector. As the major voltage is created along the terminal connector, each electrical join is sealed in a waterproof epoxy resin and the switchgear in IP66 or better waterproof enclosures [1102] and the infrastructure electrically grounded.

Each chain connector output is monitored and unless manually isolated, will be automatically connected online, if it complies with the specified electrical requirements.

A central PLC programmed Unit/Mini-computer [Control Unit] controls the entire system. The Control Unit has to achieve a specified voltage and current supply before connecting to the DC to AC inverter. The online chain connectors are connected in series one by one [via the Control Unit], until the required system voltage is achieved. There is therefore a capability for system redundancy, where under low illuminations more chain connectors can be placed on line to achieve the required outputs. Online operation time can be also ‘shared’ or distributed evenly [via programmable time allocations], over all chain connectors increasing the overall system life. System monitoring will be through either hard-wired cabling or a wireless distributed I/O for large deployments. System control will be all hard-wired.

The terminal connector serves as a connection point and cable tray for clusters in the local area [1201]. FIG. 12 illustrates a schematic of three pairs of back to back clusters that have separated electrical paths [1201] for illustration purposes only, in reality, the said electrical paths will run down the same terminal connector.

FIG. 12 illustrates the connection of several clusters [1202,1203] on the main line [1205, 2104], controlled via control lines [1204] and circuit breakers [1206]. The said main line, links directly to the power substation [2102], housing the inverters. Alternatively the outputs of the clusters can each be routed to the said substation where under low light [and therefore lower power production] conditions, can again be connected in a series group [or groups], to achieve the minimal inverter operational requirements and provide power. As the light conditions improve the said series groups can be further separated into smaller groups, each separate group then directed into power inverter combinations. This process is PLC programmed and will continue until the full power option is achieved. The same said process will occur in reverse if light conditions deteriorate.

FIG. 14a illustrates a top view of the first embodiment of the Access Platform Module. This module is specifically designed to provide workmen service, maintenance, repair and breakdown access to the deployment, principally to access the electrical distribution/pumps and PV panels in the cluster arrays. FIG. 14a specifically delineates three main components:
1. The perimeter connection component [1402a, 1402b 1402c and 1402d], which is identical in outer dimension and connection attributes to the standard modules.
2. The second major component is the internal platform [1401a, 1401b, 1401c and 1401d], which provides entrapped air floatation [up to 200 Kg payload], and an access path over the water body. A necessary action of this device is to displace water to counteract its payload by moving downwards.
3. The third major component is the flexible membrane or skirt [1403a and 1403b], which connects the first two components. The membrane allows the differential movement of the said components, whilst maintaining the integrity of the [covered] water-body.

FIG. 14b illustrates a section through the first embodiment, in particular the location of one of the four possible floatation pod positions. These pods provide floatation in the event of thermal cycling, wave action, reducing the air ballast under the internal platform.

FIGS. 14c and 14d illustrate the second and preferred embodiment of the access platform. In this embodiment the floatation pods [1405b] and entrapped air of the previous embodiment are replaced with an inflatable bag [1408c and 1405d], with an inlet valve [1406c, 1407d]. The bag/balloon pressures may be monitored through the installed PLC system if specified.

This embodiment has the water and air particulate membrane [1403b], removed and is not compliant with AWWA Standards, for US TL2 Covers. The internal platform [1401c and 1401d] is allowed to free float, but limited via the interaction of a set of articulated flaps [1403c and1408d] on hinges [1403d] with the bottom chamfer of the perimeter connection component [1402d]. The internal platform [1401c and 1401d] can be easily removed from position after deflation of the floatation bag [1408c and 1405d].

FIG. 14e illustrates a typical deployment of:
Access module [1401e],
Turret module without payload [1403e],
Turret module with a payload of the terminal connector [1404e] and the
Turret module with a payload of PV panels [1402e].

Note that the spacing of the PV panels is due/dependent on the shadow angle of the sun at the site latitude and the most efficient months of diurnal sunlight hours.

FIG. 14f illustrates a design compliant with AWWA Standards, for US TL2 Covers, which includes: a combination of turret modules with balloon/bag floatation [1408f] and ballast pipe with contents [1407f], in a drain [1406f, 2108]. Water ballast can be retained in these drains by varying to output of the sump pumps [2107] and the stabilizing turret floatation volume, to increase the ballast [weight], during and throughout the passing of a storm. The said figure also includes the terminal connector [exploded—1101 to 1105, 1404e and 1404f].

FIG. 15 illustrates a PV Panel bi-cluster array connected via a hinged gantry arm [partly shown in FIG. 1501]. The gantry arm allows flexible connection to the deployed arrays on the water body, from the shoreline of the storage [2105], for varying storage levels.

FIG. 15a illustrates a moored small [8×10] module cluster with another embodiment of a shoreline to cluster array power line. In this embodiment the waterproofed cables are placed into a flexible conduit , which is fixed on top of a number of free floating drums/buoys tethered by the conduit [1511a]. Any movement of the cluster array will result in the stretching or contraction of the linearly coiled cable [1513a and 1514a].

The controlled mooring of the array is achieved via several cables [1503a] connected from the shoreline [1505a], to the left hand topside of the array [1501a]. Each of the said cables has fixed to their midpoints another [centre] cable [1507a], such that the cables either side of the fixing points are parallel to each other. Movement of the said centre cable produces a change in the length of the hypotenuse [or distance between the shore and the cluster array]. Another identical set of cables may be placed on the right hand top side of the array to constrain the movement of the array to the left and right of the figure [FIG. 15a]. By joining the centre cable 1507a to 1508a, translational movement of this cable back and forth will result in the movement of the module array back and forth across the water-body. This may be easily achieved with a motorized capstan. Connecting another set of cables to the bottom side of the array, in an identical manner to those on the top and then connecting the bottom right hand center cable to the top left centre cable and the bottom left hand centre cable to the top right centre cable. The array would be totally constrained in position and be able to be moved [in either direction] by applying force onto one cable [via the capstan]. Variation in the water levels would be accommodated via the equalized lengthening of both the top and bottom centre cables.

FIG. 21 illustrates a typical deployment on a water body. Each cluster [2106] is connected back to back to the terminal connector [2105] and surrounded with a gap [2108], or in the case of a US EPA LT2 Cover, a flexible [membrane] drain [1108], with drain pipe [1109] and an array of sumps [2107]. The deployment is restrained via auto tensioning perimeter supports [2103], which are connected via wire to either the chain connectors [left to right] or, the terminal connectors [top & bottom]. In the case of the US EPA LT2 Cover, a [folded loop type] flexible membrane further connects to the tensioning perimeter at the shoreline and through arrowhead folded connectors to the cluster gutter perimeter.

FIGS. 21a and 21b illustrate the removal procedure for a cluster array deployed above the central plate of a typical storage. A floodable shelf [2113b and 2113c] is created adjacent to the longest side of the storage. Water is pumped into the storage to raise the storage above the normal working level of the storage, so as to flood the shelf [2113b and 2113c]. The cluster array is then floated over to the shelf [FIG. 21c]. Note that whilst the cluster is in motion the power cables are being extended via pulleys [2110b, 2110c and 2111b, 2111c], on the track [2112b, 2112c], with the gantry [2105b, 2105c], maintaining the electrical connection to the substation [2102b, 2102c]. Maintaining the electrical connection allows the shelved array to function whilst maintenance on the storage is proceeding. This type of system is only suitable for storages that do not need to be compliant with AWWA Standards, for US TL2 Covers.

As portrayed above, the modules [0903] can be connected into square clusters [0901, 0902] via module chaining and the chain connectors [0904]. The modules can also be connected into arrays of circular clusters [1607], each cluster with its own central pivot point [1604]. If each of these clusters were connected with a tether [e.g.: rod/cable etc], then the orientation of the cluster array would be controlled via the said tether. FIG. 16 illustrates this principle where the pitman arm [1609] when turned [1606] reorients the direction of the array from the top drawing to the bottom. Note that in the drawing the tether is assumed to be a rigid rod, which can in practice be replaced with a cable loop or other device(s).

For large clusters where water quality is an issue, a percentage of the population of modules [1601], can be removed [1602], so that a diurnal rotation [for example] would expose enough of the water body to eliminate water quality issues.

The said deployment [above] would be preferable for a solar generator payload, as the mass [weight] of the deployment and payload, is be supported by the buoyancy of the modular understructure. The tethering force requirement of this arrangement will only be in overcoming the inertia of the structure.

FIG. 17 illustrates the tethering inserts [1702, 1704], into the chain connector and module chain lock respectively. These inserts are designed to preferably accept either stainless steel rod [SS], or stainless steel cable. FIG. 18 illustrates a deployment of 100 modules on a square water body. The SS inserts [1804, 1805] are inserted in around the perimeter of the deployment, the number of insertion lines dependant on the site-specific elemental forces. Each Insert has a fixing point at the perimeter of the deployment [1810] From these fixing points cables are run through to the banks of the water body [1808, 1809], which connect to winches [or other devices] that through a combination of winding in/winding out of the cable in north-south and east-west directions [1806, 1807]. This process enables the deployment to be moved anywhere on the water body. This ability is preferred in the case of prolonged prevailing wind duration over a water body, where the extended duration would keep an un-tethered deployment in the downwind position and cause water quality issues.

FIG. 20 illustrates a 24 module circular cluster [2011], surrounded by a 10×10 square cluster [2014], of 36 modules with reinforcing inserts [2004], fixing points [2010] and external tethering devices/fixtures [2008, 2009, 2006 and 2007]. The central circular sub-cluster is pivoted at a central axis [2012], supported via structure [2013], which in turn is supported via the square cluster [2014]. The central cluster has an internal tethering control [2015]; enabling bi-directional controlled single axis tracking of the sun [2016].

FIG. 22 illustrates the rear view of a PV Panel and its superstructure [SS]. The superstructure is positioned on top of a turret module via ring [2201]. Two dual mounted springs 2206 and 2207, separate the altitude adjustors [2203 and 2204], from the arm [2210] and PV panel supports [2208]. The dual spring articulated tilting system of which the spring constant is be specifically designed to activate [tilt] when subjected to a specific site determined wind-loading threshold. The dual spring system comprises of a flat spring [2207] and a coil spring [2206], each spring has different resonance characteristics which are designed to antagonize each other, dampening oscillations produced by eddies generated by winds in excess of the loading threshold.

This invention is particularly useful in
1) The prevention of a large amount of evaporation from large water storage areas;
2) The prevention of rain water entering a treated water deployment;
3) Reduction the salination increase of the water storage volume;
4) Reducing the formation of Blue-green Algae in all water storage areas;
5) Allowing the control of dissolved oxygen [DO] levels in a water body;
6) Reduction of aqua weed growth in and/or above the storage water surface;
7) The system can contain redundant chain connected PV strings which can be time shared with the system or placed on line during conditions of low illumination.
8) The system can be designed so that there is a low voltage component across the major cluster area.
9) As with the connected PV Strings, the system can contain redundant clusters that can be time shared with the system or placed on line during conditions of low illumination.
10) The electrical system has an adaptability such that clusters can be connected electrically in series in varying group sizes, until an operational voltage is acquired in increasing/decreasing low light conditions . . . providing power;
11) Each PV payload can be manually fixed to any two axis angle;
12) Each PV Panel can be set up as a two axis auto sun tracking system;
13) Payload carrying capacity preferably photo voltaic generation and therefore:
   a) Grid supply power;
   b) Power to drive winches to align the array of clusters to the sun;
   c) Power to drive winches to reposition the deployment;
   d) Power to drive other localised applications.
14) The deployment [with inserts] can be tethered without the use of booms;
15) The deployment can be use as a boom with a PV payload;
16) The deployment array can be set up as a fixed single axis sun tracking cluster PV array;
17) Perimeter cluster deployments have the capability to axially support [with substructures] internal sub-clusters.

From the above, those skilled in the art will realise that this invention includes the following benefits.

The modules can be locked together in chains;
The module chains can be connected with a chain connector to form clusters;
The chain connector can be fitted with a variable number of floatation pods to buoyancy to the cluster and payload;
The chain connector can carry embedded voltage and current carrying bus bars;
The floatation pods can be profiled to create deployment ‘zones’ of greater buoyancy and therefore actively control the flow directions of the rainwater shedding of the deployment;
Quick installation of the payload infrastructure;
The payload infrastructure can be fixed/aligned into any two axis angular position, or can be fitted with an automatic two axis sun tracking system;
The module cluster array cover can be laid into any size or shape of water storage surface area;
The module clusters can support ‘missing’ modules/areas allowing the aqua culture enough oxygenation via the holes in the deployment;
The module clusters can be designed for a site specific dissolved oxygen requirement;
The module cluster deployment limiting excess light into the water reducing the formation of Algae preferably Blue-green Algae;
The module cluster deployment reducing the absorption of energy from the sun into the water body and therefore reducing the temperature;
The module cluster deployment reducing the salination increase in the water storage volume;
The module clusters can be connected via flexible membranes, perimeter drains and sumps to form a total floating cover impervious to rainwater and dust particulate pollution and their combination.
The module payload preferably a solar PV generator, permits power generation close to cities [as most water supplies are in close proximity to cities] reducing infrastructure power insertion costs;
The PV power generation can be maintained [if required] at low voltages near the water body;
Redundant chain connector strings can be connected on line to provide voltage in low light conditions [Latitude dependant];
Redundant clusters can be connected on line to provide power in low light conditions [Latitude dependant];
The module cluster deployment can be used as a PV power generating boom;
Module clusters [with inserts], can be translated [articulated if pivoted] over any part of the water body;
Module clusters can support sub-clusters [preferably circular single axis sun tracking clusters];
Modules can be deployed without ballast providing elemental, payload, superstructure, tethering and deployment conditions are favourable;
Module shells with bag/balloon floatation deployed in clustered arrays can have ballast pipes attached to the chain connectors via ballast pipe adaptors, which strengthen and stabilise the clustered arrays and are used as stands when the clusters are parked onto shelves.

Those skilled in the art will realise that this invention provides a unique arrangement to control evaporation and water quality in large water storages and at the same time take advantage of the availability of solar energy falling on the water surface to provide solar energy generation.

Those skilled in the art will realise that the present invention may be adapted for use in a range of applications and sizes and can be shaped to fit the requirements of the desired application.

1. An array of modules each adapted to support a solar collection panel for converting solar energy into electrical energy in which each module is formed from at least one half shell and when two half shells are connected form a flotation module, the outer surfaces of said at least one shell being adapted to support a solar collector and each module is adapted on two opposed edge sections for connection in line to form a chain of modules and each solar collector in said chain being connected in electrical series and/or parallel and each chain of modules being connectable laterally to form arrays of modules and each chain of solar collectors being electrically connected to other chains in series or parallel to provide the required output voltages.

2. An array of modules as claimed in claim 1 in which each shell incorporates a hole to allow air and/or water to move in and out of the formed module.

3. An array of modules as claimed in claim 2 in which the array includes modules and flotation modules to provide stability to the array.

4. An array of modules as claimed in claim 1 in which chains of modules are connected together using chain connectors that also incorporate electrical conductors.

5. An array of modules as claimed in claim 1 in which flotation devices and ballast devices are included in the array to optimise the stability of the array in all weather conditions.

6. An array of flotation modules as claimed in claim 4 which includes a control system for optimising the electrical power output of the array.
